(19) United States
(12) Patent Application Publication
(10) Pub. No.: US 2026/0309545 A1
(43) Pub. Date: Oct. 8, 2026

(54) LIGHT-DETECTING DEVICE AND ELECTRONIC APPARATUS

(71) Applicant: SONY SEMICONDUCTOR SOLUTIONS CORPORATION, KANAGAWA (JP)

(72) Inventors: Ryotaro SEKINE, KANAGAWA (JP); Masaharu NAKANISHI, KANAGAWA (JP)

(21) Appl. No.: 19/478,858

(22) PCT Filed: Apr. 17, 2024
(86) PCT No.: PCT/JP2024/015323

§ 371 Date: Oct. 27, 2025

(30) Foreign Application Priority Data
May 15, 2023 (JP) 2023-079921

(51) Int. Cl. G01J 1/44

(52) U.S. Cl. CPC G01J 1/44

(57) ABSTRACT

A light detecting device according to an embodiment of the present disclosure includes a first electrode, a second electrode provided opposed to the first electrode, multiple first structures each provided close to the first electrode between the first electrode and the second electrode, and a photoelectric conversion film provided between the multiple first structures and the second electrode.

### TECHNICAL FIELD

The present disclosure relates to a light detecting device and an electronic apparatus.

### BACKGROUND ART

An apparatus has been proposed that includes a photoelectric conversion layer including semiconductor quantum dots (Patent Literature 1).

### CITATION LIST

### Patent Literature

Patent Literature 1: International Publication No. WO 2021/161889

### SUMMARY OF THE INVENTION

It is desired to improve detection performance of a device that detects light.

It is desirable to provide a light detecting device having excellent detection performance.

A light detecting device according to one embodiment of the present disclosure includes a first electrode, a second electrode provided opposed to the first electrode, multiple first structures each provided close to the first electrode between the first electrode and the second electrode, and a photoelectric conversion film provided between the multiple first structures and the second electrode.

A light detecting device according to one embodiment of the present disclosure includes a photoelectric conversion film and multiple first structures each joined to the photoelectric conversion film with band bending.

An electronic apparatus according to one embodiment of the present disclosure includes an optical system and a light detecting device that receives light having passed through the optical system. The light detecting device includes a first electrode, a second electrode provided opposed to the first electrode, multiple first structures each provided close to the first electrode between the first electrode and the second electrode, and a photoelectric conversion film provided between the multiple first structures and the second electrode.

An electronic apparatus according to one embodiment of the present disclosure includes an optical system and a light detecting device that receives light having passed through the optical system. The light detecting device includes a photoelectric conversion film and multiple first structures each joined to the photoelectric conversion film with band bending.

### BRIEF DESCRIPTION OF THE DRAWINGS

FIG. 1 is a block diagram illustrating an exemplary schematic configuration of an imaging device that is one example of a light detecting device according to one embodiment of the present disclosure.

FIG. 2 is a diagram illustrating an example of a pixel unit of the imaging device according to the embodiment of the present disclosure.

FIG. 3 is a diagram illustrating an exemplary configuration of a pixel of the imaging device according to present disclosure.

FIG. 4A is a diagram illustrating an exemplary configuration of a photoelectric converter of the imaging device according to the embodiment of the present disclosure.

FIG. 4B is a diagram illustrating another exemplary configuration of the photoelectric converter of the imaging device according to the embodiment of the present disclosure.

FIG. 4C is a diagram illustrating another exemplary configuration of the photoelectric converter of the imaging device according to the embodiment of the present disclosure.

FIG. 5 is a diagram illustrating an example of an electric field in the photoelectric converter of the imaging device according to the embodiment of the present disclosure.

FIG. 6 is a diagram illustrating an exemplary configuration of the photoelectric converter of the imaging device according to the embodiment of the present disclosure.

FIG. 7A is a diagram illustrating an exemplary configuration of the photoelectric converter of the imaging device according to the embodiment of the present disclosure.

FIG. 7B is a diagram illustrating an exemplary configuration of the photoelectric converter of the imaging device according to the embodiment of the present disclosure.

FIG. 7C is a diagram illustrating an exemplary configuration of the photoelectric converter of the imaging device according to the embodiment of the present disclosure.

FIG. 8 is a diagram illustrating another exemplary configuration of the photoelectric converter of the imaging device according to the embodiment of the present disclosure.

FIG. 9 is a diagram illustrating an exemplary cross-sectional configuration of the imaging device according to the embodiment of the present disclosure.

FIG. 10 is a diagram illustrating an exemplary cross-sectional configuration of the imaging device according to the embodiment of the present disclosure.

FIG. 11A is a diagram illustrating an exemplary configuration of a photoelectric converter of an imaging device according to Modification Example 1 of the present disclosure.

FIG. 11B is a diagram illustrating an exemplary configuration of the photoelectric converter of the imaging device according to Modification Example 1 of the present disclosure.

FIG. 12A is a diagram illustrating an exemplary cross-sectional configuration of a photoelectric converter of an imaging device according to Modification Example 2 of the present disclosure.

FIG. 12B is a diagram illustrating an exemplary cross-sectional configuration of the photoelectric converter of the imaging device according to Modification Example 2 of the present disclosure.

FIG. 12C is a diagram illustrating an exemplary cross-sectional configuration of the photoelectric converter of the imaging device according to Modification Example 2 of the present disclosure.

FIG. 12D is a diagram illustrating another exemplary cross-sectional configuration of the photoelectric converter of the imaging device according to Modification Example 2 of the present disclosure.

FIG. 13 is a diagram illustrating an exemplary planar configuration of the photoelectric converter of the imaging device according to Modification Example 2 of the present disclosure.

FIG. 14 is a diagram illustrating an exemplary planar configuration of the photoelectric converter of the imaging device according to Modification Example 2 of the present disclosure.

FIG. 15A is a diagram illustrating another exemplary configuration of the photoelectric converter of the imaging device according to Modification Example 2 of the present disclosure.

FIG. 15B is a diagram illustrating another exemplary configuration of the photoelectric converter of the imaging device according to Modification Example 2 of the present disclosure.

FIG. 16A is a diagram illustrating an exemplary configuration of a photoelectric converter of an imaging device according to Modification Example 3.

FIG. 16B is a diagram illustrating another exemplary configuration of the photoelectric converter of the imaging device according to Modification Example 3.

FIG. 17A is a diagram illustrating another exemplary configuration of the photoelectric converter of the imaging device according to Modification Example 3.

FIG. 17B is a diagram illustrating another exemplary configuration of the photoelectric converter of the imaging device according to Modification Example 3.

FIG. 18A is a diagram illustrating an exemplary cross-sectional configuration of an imaging device according to Modification Example 4 of the present disclosure.

FIG. 18B is a diagram illustrating an exemplary cross-sectional configuration of the imaging device according to Modification Example 4 of the present disclosure.

FIG. 19A is a diagram illustrating an exemplary cross-sectional configuration of an imaging device according to Modification Example 5 of the present disclosure.

FIG. 19B is a diagram illustrating an exemplary cross-sectional configuration of the imaging device according to Modification Example 5 of the present disclosure.

FIG. 20A is a diagram illustrating an exemplary cross-sectional configuration of an imaging device according to Modification Example 6 of the present disclosure.

FIG. 20B is a diagram illustrating an exemplary cross-sectional configuration of the imaging device according to Modification Example 6 of the present disclosure.

FIG. 20C is a diagram illustrating an exemplary cross-sectional configuration of the imaging device according to Modification Example 6 of the present disclosure.

FIG. 21A is a diagram illustrating an exemplary cross-sectional configuration of an imaging device according to Modification Example 7 of the present disclosure.

FIG. 21B is a diagram illustrating an exemplary cross-sectional configuration of the imaging device according to Modification Example 7 of the present disclosure.

FIG. 22 is a block diagram illustrating an exemplary configuration of an electronic apparatus.

FIG. 23A is a diagram schematically illustrating an overall configuration of a light detecting system.

FIG. 23B is a diagram schematically illustrating an overall configuration of the light detecting system.

FIG. 24 is a block diagram depicting an example of schematic configuration of a vehicle control system.

FIG. 25 is a diagram of assistance in explaining an example of installation positions of an outside-vehicle information detecting section and an imaging section.

FIG. 26 is a view depicting an example of a schematic configuration of an endoscopic surgery system.

FIG. 27 is a block diagram depicting an example of a functional configuration of a camera head and a camera control unit (CCU).

### MODES FOR CARRYING OUT THE INVENTION

In the following, some embodiments of the present disclosure are described in detail with reference to the accompanying drawings. It is to be noted that the description is given in the following order.
1. Embodiment
2. Modification Examples
3. Application Examples
4. Practical Examples

### 1. Embodiment

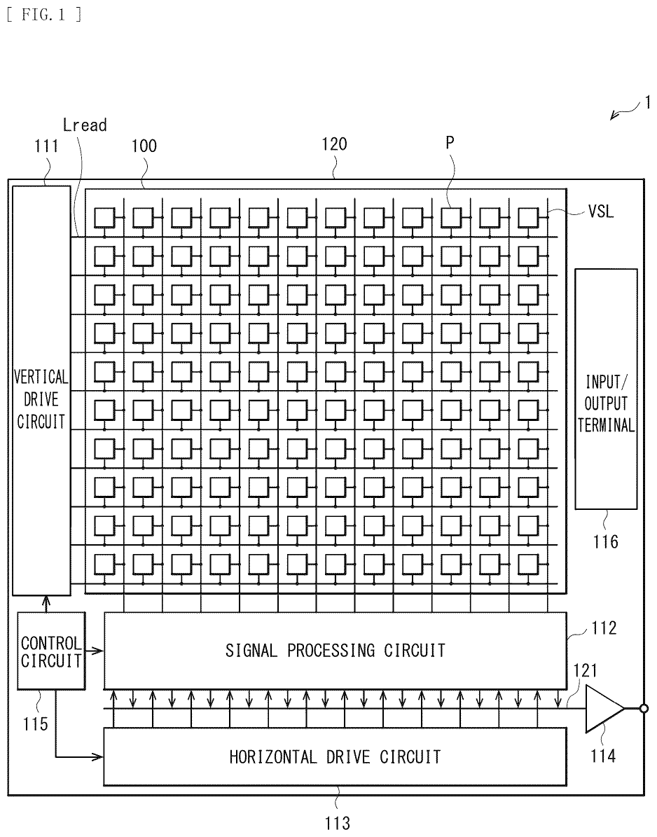

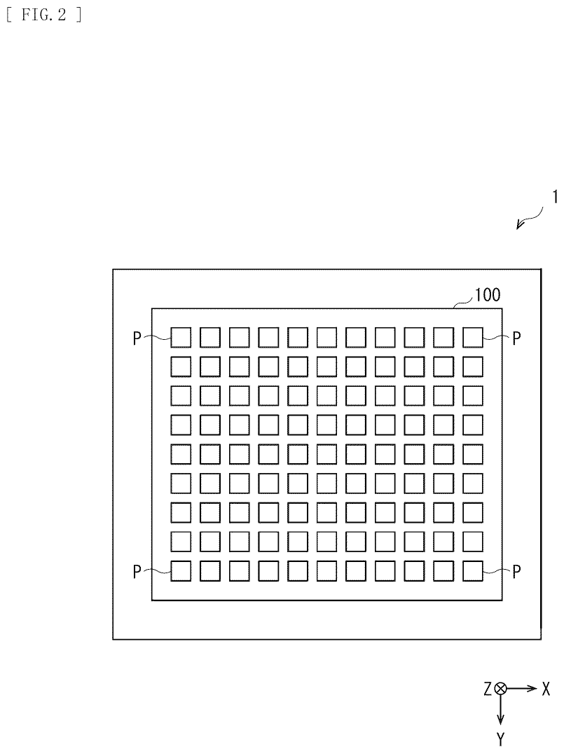

FIG. 1 is a block diagram illustrating an exemplary schematic configuration of an imaging device that is one example of a light detecting device according to an embodiment of the present disclosure. FIG. 2 is a diagram illustrating an example of a pixel unit of the imaging device according to the embodiment. The light detecting device is a device configured to detect incident light. The imaging device 1, which is a light detecting device, is configured to generate signals by receiving light having passed through an optical system. The imaging device 1 (light detecting device) includes multiple pixels P each including a photoelectric converter (photoelectric conversion element), and is configured to generate signals by photoelectrically converting incident light.

The photoelectric converter of each pixel P is, for example, a photodiode, and is configured to photoelectrically convert light. As illustrated in FIG. 2, the imaging device 1 has an imaging area (pixel unit 100) in which the multiple pixels P are two-dimensionally arranged in matrix. In other words, the pixel unit 100 is a pixel array in which the multiple pixels P are arranged.

The imaging device 1 incorporates incident light (image light) from a subject via a non-illustrated optical system including an optical lens. The imaging device 1 captures an image of the subject formed by the optical lens. The imaging device 1 generates pixel signals by photoelectrically converting the received light. The imaging device 1 is, for example, a complementary metal oxide semiconductor (CMOS) image sensor. The imaging device 1 is applicable to an electric apparatus such as a digital still camera, a video camera, or a mobile phone.

It is to be noted that, as illustrated in FIG. 2, an incident direction of light from the subject corresponds to a Z-axis direction, a lateral direction on the page orthogonal to the Z-axis direction corresponds to an X-axis direction, and a vertical direction on the page orthogonal to the Z-axis direction and the X-axis direction corresponds to a Y-axis direction. In the drawings described below, directions may be defined based on the directions of arrows in FIG. 2.

As illustrated in the example illustrated in FIG. 1, the imaging device 1 includes, for example, a vertical drive circuit 111, a signal processing circuit 112, a horizontal drive circuit 113, an output circuit 114, a control circuit 115, and an input/output terminal 116 in a surrounding area of the pixel unit 100 (pixel array). Further, the imaging device 1 is provided with a plurality of pixel drive lines Lread and a plurality of vertical signal lines VSL.

In the example illustrated in FIG. 1, the plurality of pixel drive lines Lread is wired in the pixel unit 100 for each pixel row including multiple pixels P arranged in a horizontal direction (row direction). The pixel drive lines Lread are signal lines configured to transmit signals that drive the pixels P. The pixel drive lines Lread are configured to transmit drive signals adapted to read signals from the pixels P.

Further, the vertical signal line VSL is wired in the pixel unit 100 for each pixel column including multiple pixels P arranged in a vertical direction (column direction). The vertical signal line VSL is a signal line configured to transmit a signal from the pixel P. The vertical signal line VSL is configured to transmit a signal outputted from the pixel P.

The vertical drive circuit 111 is configured by, for example, a buffer, a shift register, or an address decoder. The vertical drive circuit 111 is configured to drive each pixel P in the pixel unit 100. The vertical drive circuit 111 generates a signal to drive each pixel P, and outputs the signal to each pixel P in the pixel unit 100 via the pixel drive line Lread. The vertical drive circuit 111 generates, for example, a signal adapted to control a transfer transistor or a signal adapted to control a reset transistor, and supplies the signal to each pixel P through the pixel drive line Lread.

The signal processing circuit 112 is configured to execute signal processing on inputted pixel signals. The signal processing circuit 112 includes, for example, a load circuit unit, an analog digital (AD) conversion unit, and a horizontal selection switch. The signal outputted from each pixel P having been selectively scanned by the vertical drive circuit 111 is inputted to the signal processing circuit 112 via the vertical signal line VSL. the signal processing circuit 112 performs signal processing such as AD conversion or correlated double sampling (CDS) of the signal of the pixel P.

The horizontal drive circuit 113 is configured by, for example, a buffer, a shift register, or an address decoder. The horizontal drive circuit 113 is configured to drive the horizontal selection switch of the signal processing circuit 112. The horizontal drive circuit 113 sequentially drives the horizontal selection switches of the signal processing circuit 112 while scanning them. The signal of each pixel P transmitted through each vertical signal line VSL is subjected to the signal processing at the signal processing circuit 112, and is sequentially outputted to the horizontal signal line 121 by selective scanning by the horizontal drive circuit 113.

The output circuit 114 is configured to perform signal processing on the inputted signals, and output resultant signals. The output circuit 114 performs the signal processing on the pixel signals sequentially received from the signal processing circuit 112 via the horizontal signal lines 121, and outputs the resultant pixel signals. For example, the output circuit 114 is configured to perform buffering, black level adjustment, column variation correction, and various kinds of digital signal processing.

The control circuit 115 is configured to control each component of the imaging device 1. The control circuit 115 is configured to receive data such as a clock or data that commands an operation mode from the outside of a semiconductor substrate 120, and output data such as internal information on the imaging device 1.

The control circuit 115 includes a timing generator configured to generate various timing signals, for example. Based on the various timing signals generated by the timing generator, the control circuit 115 performs driving control on surrounding circuitry such as the vertical drive circuit 111, the signal processing circuit 112, or the horizontal drive circuit 113. The input/output terminal 116 sends and receives signals to/from the outside.

It is to be noted that the vertical drive circuit 111, the signal processing circuit 112, the horizontal drive circuit 113, the horizontal signal line 121, the output circuit 114, the control circuit 115, and the like may be provided on the semiconductor substrate 120 or may be provided on another substrate. The imaging device 1 may have a structure in which multiple substrates are stacked (layered structure).

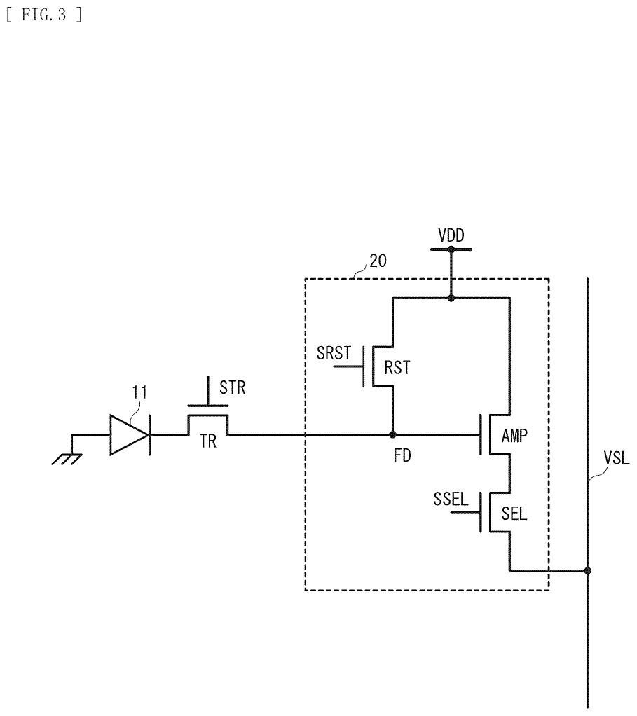

FIG. 3 is a diagram illustrating an exemplary configuration of the pixel of the imaging device according to the embodiment. The pixel P includes a photoelectric converter 11 (photoelectric conversion element), a transistor TR, and a read-out circuit 20. The photoelectric converter 11 is configured to generate signals by receiving light. The read-out circuit 20 is configured to output signals based on electric charges generated through photoelectric conversion.

The photoelectric converter 11 is configured to generate electric charges through the photoelectric conversion. In the example illustrated in FIG. 3, the photoelectric converter 11 converts incident light into electric charges. The photoelectric converter 11 generates electric charges in accordance with a light reception amount through the photoelectric conversion.

The read-out circuit 20 includes, for example, a floating diffusion FD, a transistor RST, a transistor AMP, and a transistor SEL. The transistor TR, the transistor RST, the transistor AMP, and the transistor SEL are MOS transistors (MOSFETs) each including gate, source, and drain terminals.

In the example illustrated in FIG. 3, the transistor TR, the transistor AMP, the transistor SEL, and the transistor RST are each configured by a NMOS transistor. It is to be noted that the transistor of the pixel P may be configured by a PMOS transistor. It is to be noted that the read-out circuit 20 may include the transistor TR.

The transistor TR is configured to transfer the electric charges generated through the photoelectric conversion at the photoelectric converter 11 to the floating diffusion FD. As illustrated in FIG. 3, the transistor TR electrically couples or uncouples the photoelectric converter 11 to/from the floating diffusion FD by being controlled based on a signal STR. The transistor TR is a transfer transistor, and is configured to transfer the accumulated electric charges generated through the photoelectric conversion at the photoelectric converter 11 to the floating diffusion FD.

The floating diffusion FD is an accumulation unit, and is configured to accumulate the transferred electric charges. The floating diffusion FD may accumulate the electric charges generated through the photoelectrical conversion at the photoelectric converter 11. In other words, the floating diffusion FD is a holding unit configured to hold the transferred electric charges. The floating diffusion FD accumulates the transferred electric charges and converts the electric charges into a voltage in accordance with a capacity of the floating diffusion FD.

The transistor AMP is configured to generate signals based on the electric charges accumulated in the floating diffusion FD and output the signals. As illustrated in FIG. 3, the gate of the transistor AMP is electrically coupled to the floating diffusion FD, and receives the voltage generated through the conversion at the floating diffusion FD.

The drain of the transistor AMP is coupled to a power line to which a power voltage VDD is to be supplied. The source of the transistor AMP is coupled to the vertical signal line VSL via the transistor SEL. The transistor AMP is an amplifier transistor, and may generate signals based on the electric charges accumulated in the floating diffusion FD, i.e., signals based on the voltage of the floating diffusion FD, and output the signals to the vertical signal line VSL.

The transistor SEL is configured to control the output of the pixel signals. The transistor SEL is controlled based on a signal SSEL, and is configured to output a signal from the transistor AMP to the vertical signal line VSL. The transistor SEL may control an output timing of the pixel signal. It is to be noted that the transistor SEL may be provided between the power line to which the power voltage VDD is to be supplied and the transistor AMP. Alternatively, the transistor SEL may be omitted, as appropriate.

The transistor RST is configured to reset the voltage of the floating diffusion FD. In the example illustrated in FIG. 3, the transistor RST is electrically coupled to the power line to which the power voltage VDD is to be supplied, and is configured to reset the electric charge of the pixel P. The transistor RST may be controlled based on a signal SRST, may reset the electric charges accumulated in the floating diffusion FD, and may reset the voltage of the floating diffusion FD. It is to be noted that the transistor RST may discharge the electric charges accumulated in the photoelectric converter 11 via the transistor TR. The transistor RST is a reset transistor.

It is to be noted that a configuration of the read-out circuit 20 may be modified as appropriate. For example, the read-out circuit 20 may include a capacitative element configured to accumulate electric charges. Alternatively, the read-out circuit 20 may include, for example, an integrating circuit, and may be configured to convert signal electric charges into voltage signals. Alternatively, the read-out circuit 20 may be configured to change conversion efficiency (gain) in converting electric charges into voltage. For example, the read-out circuit 20 may include a switching transistor usable in setting the conversion efficiency.

The vertical drive circuit 111 (refer to FIG. 1) supplies a control signal to the gates of the transistor TR, the transistor SEL, the transistor RST, and the like of each pixel P via the pixel drive line Lread described above, to thereby bring the transistors into an ON state (conductive state) or an OFF state (non-conductive state).

The plurality of pixel drive lines Lread of the imaging device 1 includes a wiring line that transmits the signal STR adapted to control the transistor TR, a wiring line that transmits the signal SSEL adapted to control the transistor SEL, and a wiring line that transmits the signal SRST adapted to control the transistor RST, for example.

The transistor TR, the transistor SEL, the transistor RST, and the like are subjected to ON-OFF control by the vertical drive circuit 111. The vertical drive circuit 111 causes each pixel P to output the pixel signal to the vertical signal line VSL by controlling the transistor TR and the read-out circuit 20 of each pixel P. The vertical drive circuit 111 may perform control of reading the pixel signal from each pixel P to the vertical signal line VSL.

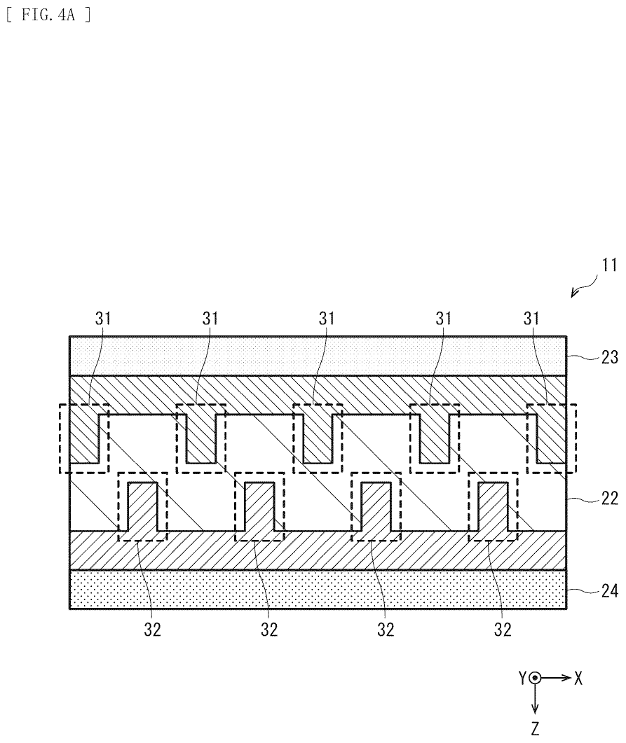

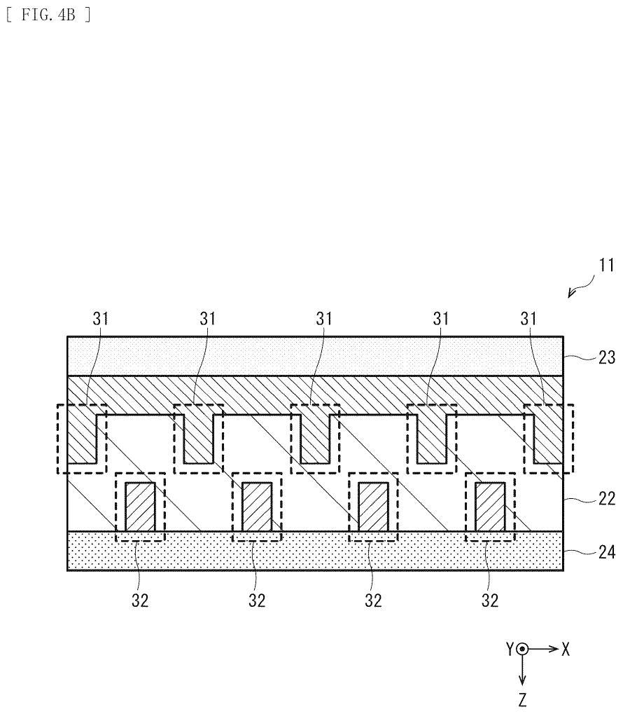

FIG. 4A is a diagram illustrating an exemplary configuration of the photoelectric converter of the imaging device according to the embodiment. As in the example illustrated in FIG. 4A, the photoelectric converter 11 (photoelectric conversion element) of each pixel P of the imaging device 1 includes a photoelectric conversion film 22, an upper electrode 23, and a lower electrode 24. Further, the photoelectric converter 11 includes multiple structures 31 and multiple structures 32.

The photoelectric conversion film 22 generates electric charges through photoelectric conversion. The photoelectric conversion film 22 may photoelectrically convert incident light to generate electric charges in accordance a light reception amount. In other words, the photoelectric conversion film 22 is a photoelectric conversion layer. The photoelectric conversion film 22 (photoelectric conversion layer) includes, for example, quantum dots, and is configured to generate electric charges upon receiving infrared light. The photoelectric conversion film 22 is configured to generate electric charges by photoelectrically converting light within a wavelength range such as a near-infrared (NIR) or a short-wavelength infrared (SWIR) range.

In one example, the imaging device 1 is provided with the photoelectric conversion film 22 including the quantum dots for each pixel P. It is to be noted that the photoelectric conversion film 22 may be configured to generate electric charges upon receiving visible light. As the photoelectric conversion film 22, a photoelectric conversion film including an organic material may be provided. Further, as the photoelectric conversion film 22, a photoelectric conversion film including an inorganic material may be provided.

The photoelectric conversion film 22 may include, for example, an organic compound semiconductor, an inorganic compound semiconductor, germanium (Ge), silicon germanium (SiGe), or silicon (Si). The photoelectric conversion film 22 may include a mixed crystal of group IV elements, a group III-V compound semiconductor, a group II-VI compound semiconductor, a CIGS-based (chalcopyrite-based) material, an organic-inorganic perovskite (e.g., MAPbI₃, MAPbBr₃, MAPbCl₃, etc.), or a Mg₂Si material (Mg₂Si, Mg₂Ge, Mg₂Sn, etc.).

The material of the photoelectric conversion film 22 may be selected in accordance with a wavelength range of incident light that is a measurement target, for example. In a case of quantum dots (QD), an absorption wavelength is adjustable based on a core material and a particle diameter of the core material, for example.

The upper electrode 23 is an electrode shared by the photoelectric conversion films 22 of the multiple pixels P, and is provided on one surface of the photoelectric conversion film 22, for example. The lower electrode 24 is provided on another surface of the photoelectric conversion film 22 for each pixel P or a plurality of pixels P. The upper electrode 23 and the lower electrode 24 may be provided opposed to each other.

The upper electrode 23 and the lower electrode 24 are disposed with the photoelectric conversion film 22 interposed therebetween. The lower electrode 24 is provided opposed to the upper electrode 23 with part of the structures 31 and 32 and part of the photoelectric conversion film 22 interposed therebetween. The upper electrode 23 is an upper electrode of the photoelectric conversion film 22, and the lower electrode 24 is a lower electrode of the photoelectric conversion film 22.

The upper electrode 23 is an electrode shared by the multiple pixels P. In other words, the upper electrode 23 is a common electrode. The lower electrode 24 is, for example, an electrode usable for reading out the electric charges generated through the conversion at the photoelectric conversion film 22. In other words, the lower electrode 24 is a read-out electrode. The upper electrode 23 and the lower electrode 24 are electrically coupled to, for example, circuitry provided on the semiconductor substrate 120 described above via respective wiring lines, electrodes, or the like different from each other.

The upper electrode 23 and the lower electrode 24 are each a transparent electrode, for example, and include a material such as indium tin oxide (ITO) or indium zinc oxide (IZO). The upper electrode 23 and the lower electrode 24 may include another tin oxide material or another zinc oxide material, or may include another transparent electrically-conductive material. It is to be noted that the lower electrode 24 may be formed by a metal material having high reflectance.

The photoelectric converter 11 includes the structures 31 and the structures 32 and is configured to generate an electric field (potential gradient) in the photoelectric conversion film 22. As in the example illustrated in FIG. 4A, for example, the structures 31 and the structures 32 are columnar structures. The structures 31 are provided on the one surface of the photoelectric conversion film 22.

In the imaging device 1, for example, the multiple structures 31 are provided close to the upper electrode 23 between the upper electrode 23 and the lower electrode 24. In the example illustrated in FIG. 4A, the structures 31 are located between the photoelectric conversion film 22 and the upper electrode 23, and are provided on the upper electrode 23.

The multiple structures 31 in each pixel P are arranged adjacent to each other in the X-axis direction with a part of the photoelectric conversion film 22 interposed therebetween. For example, the multiple structures 31 may be arranged in the X-axis direction and the Y-axis direction crossing the X-axis direction in plan view.

In each pixel P, the structures 31 are disposed with respect to the photoelectric conversion film 22, and may be provided in contact with the photoelectric conversion film 22. The structures 31 and the photoelectric conversion film 22 are joined to each other with band bending. The structures 31 cause the band bending at a joint interface of the photoelectric conversion film 22, allowing an electric field (electrical field) to be applied to the photoelectric conversion film 22.

The structures 32 are provided on the other surface of the photoelectric conversion film 22. For example, the multiple structures 32 are provided close to the lower electrode 24 between the upper electrode 23 and the lower electrode 24. In the example illustrated in FIG. 4A, the structures 32 are located between the photoelectric conversion film 22 and the lower electrode 24, and are provided on the lower electrode 24. The structures 31 and the structures 32 are provided separately from each other with the photoelectric conversion film 22 interposed therebetween.

In each pixel P, the multiple structures 32 are arranged adjacent to each other in the X-axis direction with a part of the photoelectric conversion film 22 interposed therebetween. For example, the multiple structures 32 may be arranged in the X-axis direction and the Y-axis direction in plan view.

In each pixel P, the structures 32 are disposed with respect to the photoelectric conversion film 22, and may be provided in contact with the photoelectric conversion film 22. The structures 32 and the photoelectric conversion film 22 are joined to each other with band bending. The structures 32 cause the band bending at a joint interface of the photoelectric conversion film 22, allowing an electric field to be applied to the photoelectric conversion film 22.

It is to be noted that the structures 31 and the structures 32 may be regarded as projections that are projecting parts. The structures 31 project from the upper electrode 23 toward the photoelectric conversion film 22. The structures 31 are convex portions extending from the upper electrode 23 toward the photoelectric conversion film 22. In other words, the structures 31 are protrusions protruding toward the inside of the photoelectric conversion film 22.

Further, the structures 32 project from the lower electrode 24 toward the photoelectric conversion film 22. The structures 32 are convex portions extending from the lower electrode 24 toward the photoelectric conversion film 22. In other words, the structure 32 are protrusions protruding toward the inside the photoelectric conversion film 22.

It is to be noted that the multiple structures 31 may be integrated with each other or may be separated from each other. In the example illustrated in FIG. 4A, the multiple structures 31 are successively formed and integrated with each other. In other words, the multiple structures 31 are integrated into a single structure including a plurality of structural portions. Likewise, the multiple structures 32 may be integrated with each other or may be separated from each other. In the example illustrated in FIG. 4A, the multiple structures 32 are successively formed and integrated with each other. In other words, the multiple structures 32 may be integrated into a single structure including a plurality of structural portions. As in the example illustrated in FIG. 4B, the multiple structures 32 may be separated from each other.

In the example illustrated in FIG. 4A, each of the structures 31 and the structures 32 is a portion having a comb-teeth shape (comb-teeth portion). For example, each of the structures 31 and the structures 32 may be an electrode having a comb-teeth shape. The multiple structures 31 and 32, which are comb-teeth portions, are formed to engage with each other. It is to be noted that the number and arrangement of the structures 31 and 32 in each pixel P are not limited those illustrated in the drawings.

The structure 31 and the structure 32 include respective materials different in work function from each other. For example, the structure 31 and the structure 32 include respective materials different from each other. The structure 31 and the structure 32 include, for example, a metal material or a semiconductor material. In one example, the structure 31 includes a material having a higher work function than that of the structure 32, and thus has a higher work function than the structure 32.

In another example, the structure 31 includes a material having a lower work function than that of the structure 32, and thus has a lower work function than the structure 32. For example, in a case of a pixel P to be read by collecting electrons from the lower electrode 24, the structure 31 may include a material having a higher work function than that of the structure 32. Further, in a case of a pixel P to be read by collecting holes from the lower electrode 24, the structure 31 may include a material having a lower work function than that of the structure 32.

In the imaging device 1, the structures 31 and the structures 32 may be provided to form a potential gradient in the photoelectric conversion film 22. For example, a potential barrier is formed between the structure 31 and the photoelectric conversion film 22 by the structure 31. Further, a potential barrier is formed between the structure 32 and the photoelectric conversion film 22 by the structure 32. Providing the structures 31 and the structures 32 allows an intense electric field, such as an electric field in a case of a Schottky junction, to be formed in the photoelectric conversion film 22.

In one example, the structure 31 is an electrode including a metal material, and is joined to the photoelectric conversion film 22 by means of the Schottky junction. A Schottky barrier is formed between the structure 31 and the photoelectric conversion film 22 by the structure 31. For example, the structure 31 and the photoelectric conversion film 22 are coupled by means of the Schottky junction for electrons.

In one example, the structure 32 is an electrode including a metal material, and is joined to the photoelectric conversion film 22 by means of the Schottky junction. A Schottky barrier is formed between the structure 32 and the photoelectric conversion film 22 by the structure 32. For example, in a case where the structure 31 includes a metal material having a large work function with respect to the photoelectric conversion film 22, the structure 32 may include a material having a small work function with respect to the photoelectric conversion film 22. In this case, a gradient in which a potential gradually decreases from the photoelectric conversion film 22 toward the structure 32 may be generated for the electrons. In this way, an intense electric field may be formed in the photoelectric conversion film 22 by means of the Schottky junction.

It is to be noted that the structure 31 and the structure 32 may each include, for example, a semiconductor oxide material such as indium gallium zinc oxide (IGZO). Alternatively, each of the structure 31 and the structure 32 may include an organic semiconductor material. The structure 31 may be, for example, a transparent electric-charge transport layer (also referred to as a blocking layer). The structure 32 may be, for example, a hole transport layer (also referred to as an electron blocking layer).

The materials of the structure 31 and the structure 32 may be selected in accordance with the material, work function, electron affinity, carrier (signal electric charge), or the like of the photoelectric conversion film 22. For example, the structure 31 may have a lower work function than the structure 32, or may have a higher work function than the structure 32.

The structure 31 and the structure 32 may be each configured by a structure (electrode) to be joined to the photoelectric conversion film 22 with band bending. The Schottky junction and the band bending depend on the work function of the material to be joined. The work function may be determined by photoelectric spectroscopy. Further, the shape of the structure may be confirmed by a SEM or TEM analysis. Further, the materials of the structure 31, the structure 32, the photoelectric conversion film 22 may be confirmed by a composition analysis such as SEM-EDX or XPS. Combining these composition analyses and photoelectric spectroscopy achieve identification between the material of the structure 31 and the material of the structure 32.

It is to be noted that the upper electrode 23 and the structure 31 may include the same material. The structure 31 and the upper electrode 23 may be integrated with each other. The structure 31 may also serve as the upper electrode of the photoelectric conversion film 22. In the example illustrated in FIG. 4C, for example, the structure 31 also serves as an upper electrode (common electrode) of the photoelectric converter 11. In other words, the multiple structures 31 may be a part of the upper electrode.

In addition, the lower electrode 24 and the structure 32 may include the same material. The structure 32 may be integrated with the lower electrode 24. The structure 32 may also serve as the lower electrode of the photoelectric conversion film 22. In the example illustrated in FIG. 4C, the structure 32 also serves as a lower electrode (read-out electrode) of the photoelectric converter 11. In other words, the multiple structures 32 are a part of the lower electrode. It is to be noted that the structures 31 and 32 may be formed by a method such as lithography or etching.

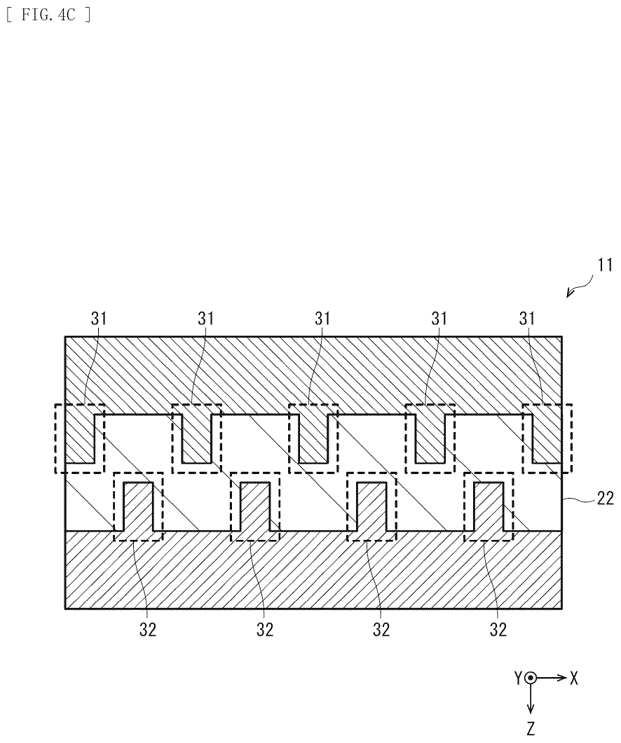

FIG. 5 is a diagram illustrating an example of an electric field in the photoelectric converter of the imaging device according to the embodiment. In FIG. 5, solid lines in the photoelectric conversion film 22 schematically indicate equipotential lines. In addition, in FIG. 5, filled circles schematically indicate signal electric charges (e.g., electrons), and broken arrows schematically indicate trajectories of the signal electric charges (travel trajectories). It is to be noted that open arrows schematically indicate light incident on the photoelectric converter 11 including the photoelectric conversion film 22.

Providing the structures 31 and the structures 32 as described above may generate an electric filed (potential gradient) in the photoelectric conversion film 22 as in the example illustrated in FIG. 5. Accordingly, as indicated by the broken arrows in FIG. 5, the electric charges generated through the photoelectric conversion at the photoelectric converter 11 move toward the structures 32. In the example illustrated in FIG. 5, the electric field applied by the structures 31 and the structures 32 allows the signal electric charges generated by the photoelectric converter 11 to be efficiently transferred toward the structures 32.

According to the embodiment described above, providing the structures 31 and 32, that are protrusions with respect to the photoelectric conversion film 22, makes it possible to form an electric field (potential gradient) inside the photoelectric conversion film 22. This allows the signal electric charges generated through the conversion to be efficiently collected. In particular, even in a case of microscopic pixels, it is possible to suppress a decrease in quantum efficiency (QE). Further, it is possible to transfer the signal electric charges toward the read-out electrode (e.g., the lower electrode 24) regardless of locations of the generation of the signal electric charges inside the photoelectric conversion film 22.

Further, the imaging device 1 is configured to cause the photoelectric converter 11 to generate an intense electric field using the band bending at the joint portion. Accordingly, even in a case where the photoelectric conversion film 22 includes a material with low mobility (e.g., quantum dots or an organic material), the signal electric charges are allowed to reach the read-out electrode. This suppresses recombination and extinguishment of the electric charges generated through the photoelectric conversion, and suppresses a decrease in the quantum efficiency. It is possible to improve sensitivity with respect to incident light.

It is to be noted that a voltage may be applied to the structures 31 and 32 and the photoelectric conversion film 22 by the upper electrode 23 and the lower electrode 24. For example, a voltage is applied between the electrodes when the signal electric charges are to be read. This allows the electric charges to be efficiently transferred from the photoelectric conversion film 22.

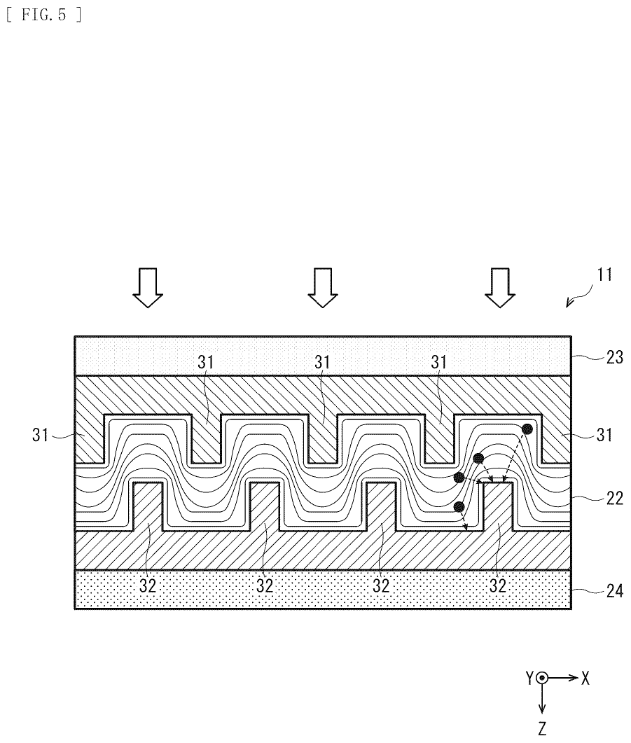

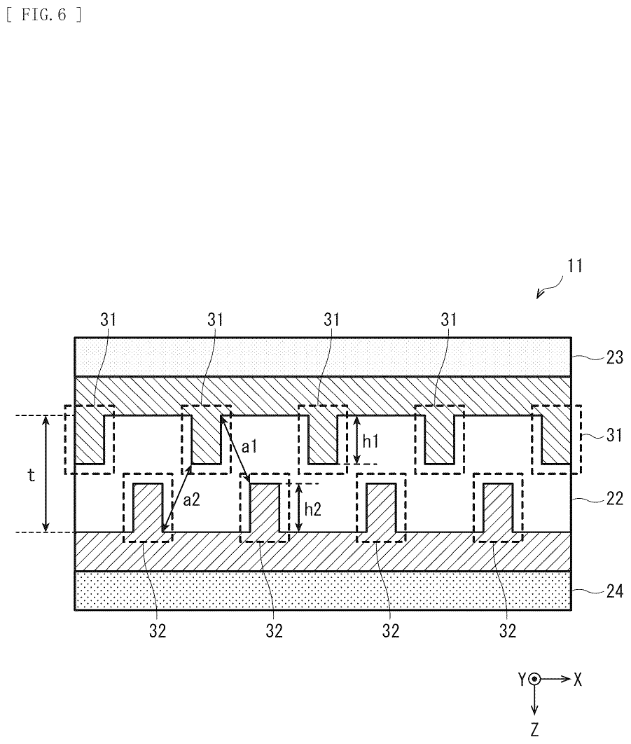

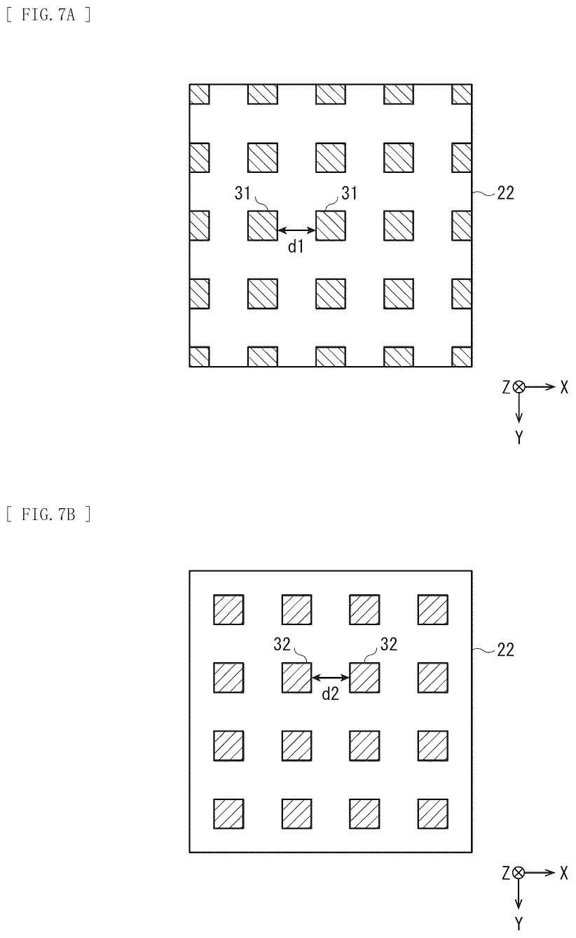

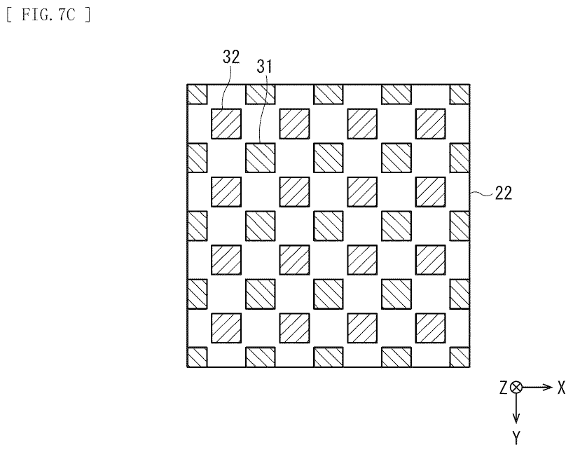

FIG. 6 and FIGS. 7A to 7C are diagrams illustrating an exemplary configuration of the photoelectric converter of the imaging device according to the embodiment. FIG. 6 illustrates an exemplary cross-sectional configuration of the photoelectric converter 11. FIG. 7A illustrates an exemplary planar configuration of the multiple structures 31 of the photoelectric converter 11. FIG. 7B illustrates an exemplary planar configuration of the multiple structures 32 of the photoelectric converter 11. Further, FIG. 7C illustrates the structures 31 and the structures 32 of the photoelectric converter 11, and a positional relation between the structures 31 and the structures 32.

In each pixel P of the imaging device 1, an interval between the structure 31 and the structure 32 may be, for example, less than or equal to 1 μm. As illustrated in FIG. 6, an interval al between a lower end (bottom) of the structure 31 and an upper end (top) of the structure 32 may be less than or equal to 1 μm. Further, an interval a2 between an upper end (top) of the structure 31 and a lower end (bottom) of the structure 32 may be less than or equal to 1 μm. The imaging device 1 having such a configuration makes it possible to reduce a moving distance of the signal electric charge generated through the photoelectric conversion and efficiently suppresses a decrease in the quantum efficiency.

As in the example illustrated in FIG. 6, the structure 31 has a height (length) h1 which may be less than or equal to 1 μm in a stacking direction (the Z-axis direction in FIG. 6) of the upper electrode 23, the photoelectric conversion film 22, the lower electrode 24, and the like, for example. In addition, the structure 32 has a height h2 which may be less than or equal to 1 μm. The height h1 of the structure 31 and the height h2 of the structure 32 are so adjusted that the moving distance of the signal electric charge becomes about 1 μm. This makes it possible to suppress a decrease in the quantum efficiency.

Further, as illustrated in FIG. 7A, an interval d1 between each adjacent ones of the multiple structures 31 may be, for example, less than or equal to 1 μm. Further, as illustrated in FIG. 7B, an interval d2 between each adjacent ones of the multiple structures 32 may be, for example, less than or equal to 1 μm. In this case, it is possible to effectively generate an electric field to form a depletion layer between the multiple structures 31 and between the multiple structures 32. This makes it possible to suppress a decrease in the quantum efficiency in a case of the photoelectric conversion film 22 having a large film thickness.

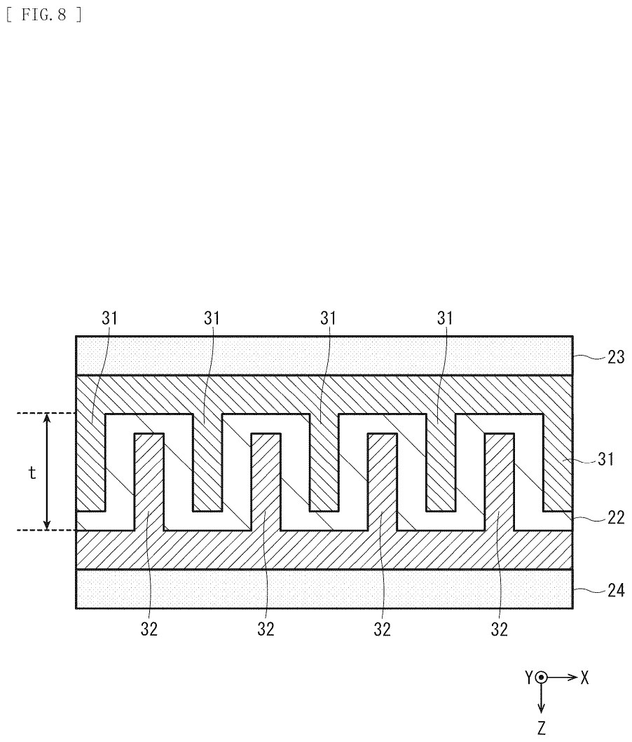

FIG. 8 is a diagram illustrating another exemplary configuration of the photoelectric converter of the imaging device according to the embodiment. As in the example illustrated in FIG. 8, the structure 31 and the structure 32 are provided with a part of the photoelectric conversion film 22 interposed therebetween in the XY planar direction. In the example illustrated in FIG. 8, each adjacent ones of the multiple structures 31 are arranged with a part of the photoelectric conversion film 22 and a part of the structure 32 interposed therebetween.

Further, each adjacent ones of the multiple structures 32 may be arranged with a part of the photoelectric conversion film 22 and a part of the structure 31 interposed therebetween. In the example illustrated in FIG. 8, the multiple structures 31 and the multiple structures 32 are provided to overlap with each other. The imaging device 1 having such a configuration makes it possible to suppress generation of a non-depletion region inside the photoelectric conversion film 22 even in a case of the photoelectric conversion film 22 having a large thickness (film thickness) t (e.g., t≥2 μm) and suppress a decrease in the quantum efficiency.

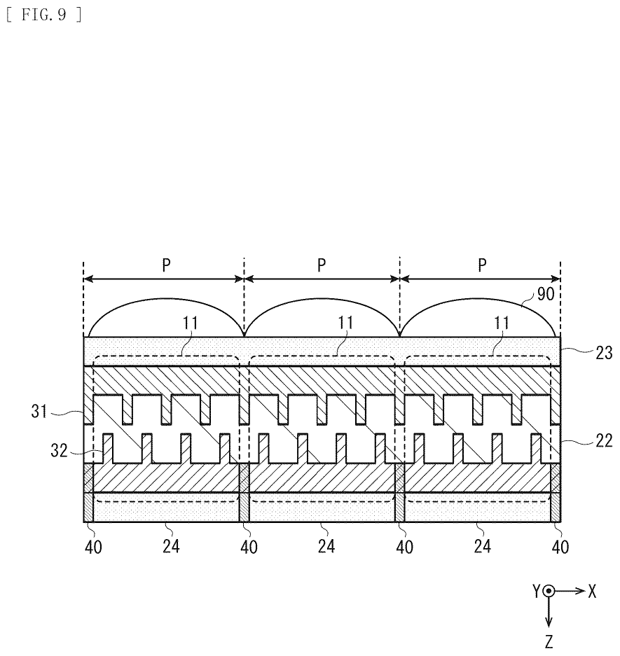

FIG. 9 is a diagram illustrating an exemplary cross-sectional configuration of the imaging device according to the embodiment. The imaging device 1 includes the multiple pixels P each including the photoelectric converter 11 described above, a lens 90, and a pixel separator 40. The lens 90 guides light entering from the above toward the photoelectric converter 11. The lens 90 (lens unit) is an optical member which is also referred to as an on-chip lens.

The lens 90 is disposed above the photoelectric converter 11 for each pixel P or for a plurality of pixels P, for example. Light from the subject is incident on the lens 90 via an optical system such as an imaging lens. The photoelectric converter 11 of the pixel P photoelectrically converts the incident light via the lens 90.

The pixel separator 40 includes, for example, an insulating material, and is provided at a boundary between each adjacent ones of the multiple pixels P. In the example illustrated in FIG. 9, the pixel separator 40 is provided between the lower electrodes 24 of each adjacent ones of the multiple pixels P. The pixel separator 40 may include an insulating film (insulator) such as an oxide film (e.g., a silicon oxide film) or a nitride film (e.g., a silicon nitride film).

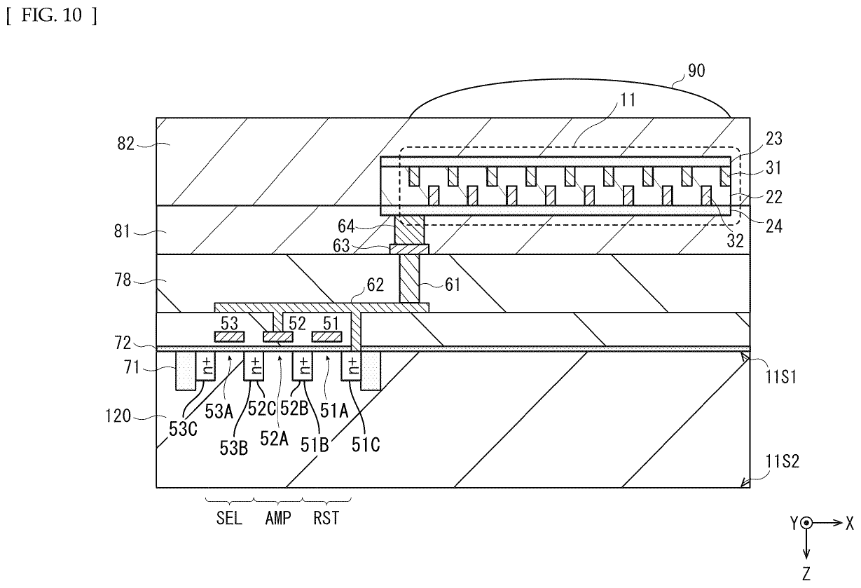

FIG. 10 is a diagram illustrating an exemplary cross-sectional configuration of the imaging device according to the embodiment. As illustrated in FIG. 10, the imaging device 1 includes the semiconductor substrate 120. The semiconductor substrate 120 includes a first surface 11S1 and a second surface 11S2 opposed to each other. The second surface 11S2 is a surface opposite to the first surface 11S1. The semiconductor substrate 120 is configured by, for example, a silicon substrate.

The semiconductor substrate 120 may also be referred to as a semiconductor film. The semiconductor substrate 120 is provided with the read-out circuit 20 described above with reference to FIG. 3. The lower electrode 24 of the photoelectric converter 11 is electrically coupled to the gate of the floating diffusion FD and the gate of the transistor AMP. The photoelectric converter 11 is disposed above the semiconductor substrate 120. Here, a light incident surface of the semiconductor substrate 120 corresponds to an upper side, and an opposite side of the semiconductor substrate 120 corresponds to a lower side.

The lower electrode 24 of the photoelectric converter 11 is formed on the interlayer insulating layer 81. On the lower electrode 24, the multiple structures 32, the photoelectric conversion film 22, the multiple structures 31, and the upper electrode 23 are formed. A protection layer 82 is formed on the entire surface including the upper electrode 23. The lens 90 is provided on the protection layer 82. The interlayer insulating layer 81 and the protection layer 82 each include an insulating material such as SiO or SiN.

An element separation region 71 and an oxide film 72 are formed on the first surface 11S1 of the semiconductor substrate 120. The transistor RST, the transistor AMP, the transistor SEL, the floating diffusion FD, and the like of the read-out circuit 20 are provided on the first surface 11S1 of the semiconductor substrate 120.

The transistor RST includes a gate 51, a channel formation region 51A, and source/drain regions 51B and 51C. The source/drain region 51C of the transistor RST also serves as the floating diffusion FD. The source/drain region 51B is electrically coupled to the power line to which the power voltage VDD is to be supplied.

The lower electrode 24 of the photoelectric converter 11 is electrically coupled to the source/drain region 51C of the transistor RST (floating diffusion FD) via a coupling hole 64 formed in the interlayer insulating layer 81, a pad 63, a contact hole 61 formed in the interlayer insulating layer 78, and a wiring layer 62 formed on the interlayer insulating layer 78.

The transistor AMP includes a gate 52, a channel formation region 52A, and source/drain regions 52B and 52C. The gate 52 is coupled to the lower electrode 24 and the source/drain region 51C of the transistor RST (floating diffusion FD) via the wiring layer 62. Further, the source/drain region 52B shares a region with the source/drain region 51B of the transistor RST, and is coupled to the power line to which the power voltage VDD is to be supplied.

The transistor SEL includes a gate 53, a channel formation region 53A, and source/drain regions 53B and 53C. The source/drain region 53B shares a region with the source/drain region 52C of the transistor AMP, and the source/drain region 53C is coupled to the vertical signal line VSL.

### <Workings and Effects>

The light detecting device according to the present embodiment includes a first electrode (e.g., the upper electrode 23), a second electrode (e.g., the lower electrode 24) provided opposed to the first electrode, multiple first structures (e.g., the structures 31) each provided close to the first electrode between the first electrode and the second electrode, and a photoelectric conversion film (the photoelectric conversion film 22) provided between the multiple first structures and the second electrode.

In the light detecting device (the imaging device 1) according to the present embodiment, the photoelectric conversion film 22 is provided between the multiple structures 31 and the lower electrode 24. This allows the structures 31 to generate an electric field in the photoelectric conversion film 22, improving the quantum efficiency. It is therefore possible to achieve the light detecting device having excellent detection performance.

Next, a description will be given of modification examples of the present disclosure. In the following, constituting elements similar to those of the above-described embodiment are denoted with the same reference numerals to omit the description thereof as appropriate.

### 2. Modification Examples

### 2-1. Modification Example 1

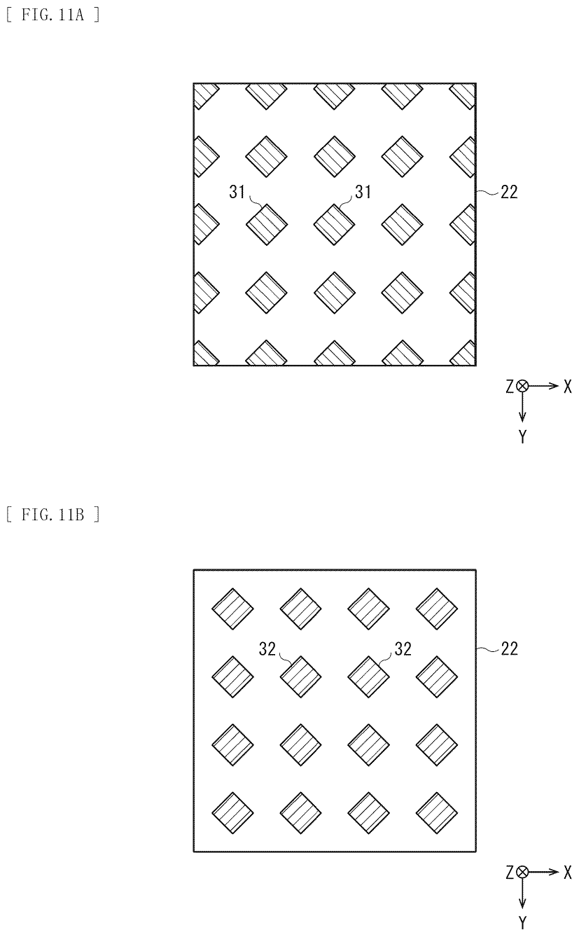

Although the exemplary configurations of the structures 31 and the structures 32 are described in the above-described embodiment, the configurations of the structures 31 and the structures 32 are not limited to the examples described above. FIGS. 11A and 11B are diagrams illustrating an exemplary configuration of a photoelectric converter of an imaging device according to Modification Example 1 of the present disclosure. FIG. 11A illustrates an exemplary planar configuration of the multiple structures of the photoelectric converter 11. FIG. 11B illustrates an exemplary planar configuration of the multiple structures 32 of the photoelectric converter 11.

As illustrated in FIGS. 11A and 11B, the structures 31 and the structures 32 in the photoelectric converter 11 may be shifted by 45° with respect to the X-axis direction and the Y-axis direction. The structures 31 and the structures 32 may be shifted by 45° with respect to the shape of the pixel P or the photoelectric converter 11.

### 2-2. Modification Example 2

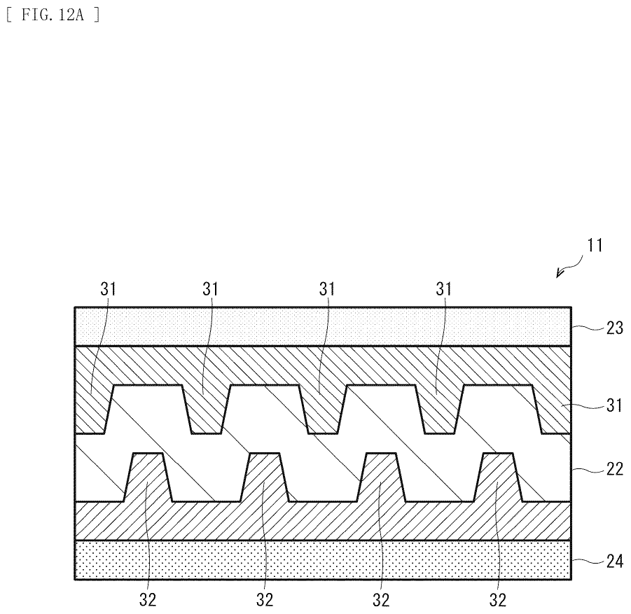

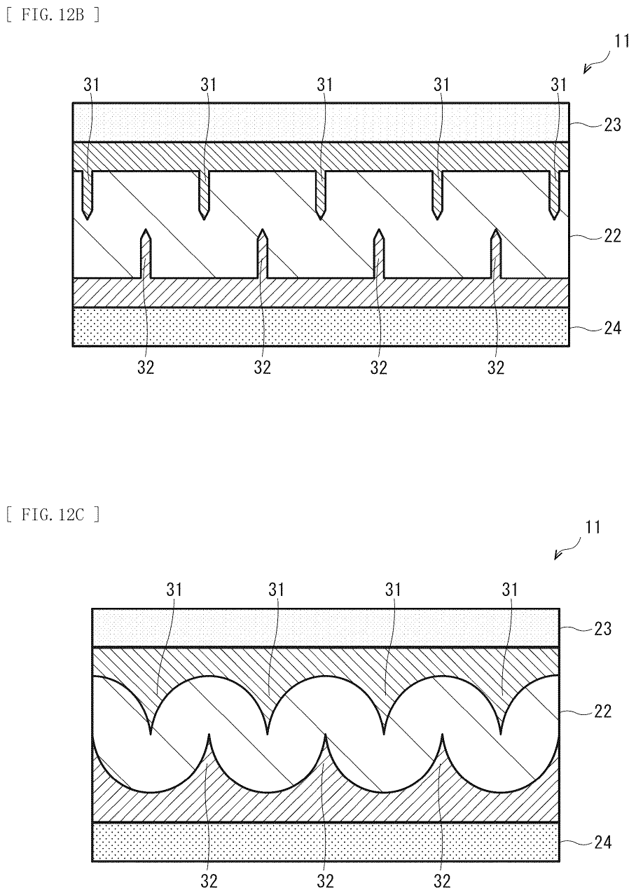

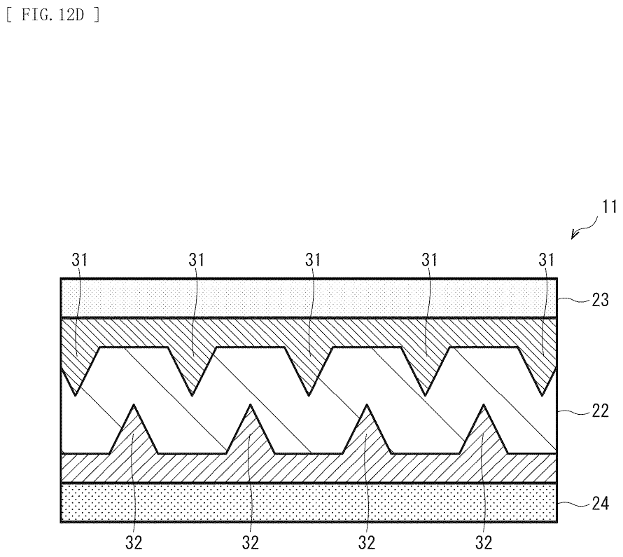

FIG. 12A is a diagram illustrating an exemplary cross-sectional configuration of an imaging device according to Modification Example 2. The shape of each of the structures 31 and the structures 32 may be modified as appropriate, and may each have a trapezoid shape as in the example illustrated in FIG. 12A. The structures 31 and the structures 32 may each have a truncated cone shape. The structures 31 and the structures 32 may each have a taper (inclined portion). In other words, the structures 31 and the structures 32 may each have a tapered shape.

FIG. 12B to FIG. 12D are diagrams illustrating another exemplary cross-sectional configuration of the imaging device according to Modification Example 2. As in the example illustrated in FIG. 12B, the structures 31 and the structures 32 may each have a needle-like structure. Alternatively, as in the example illustrated in FIG. 12C, for example, the structures 31 and the structures 32 may each have a parabolic structure. In the example illustrated in FIG. 12D, the structures 31 and the structures 32 may each have a conical shape or a pyramid shape.

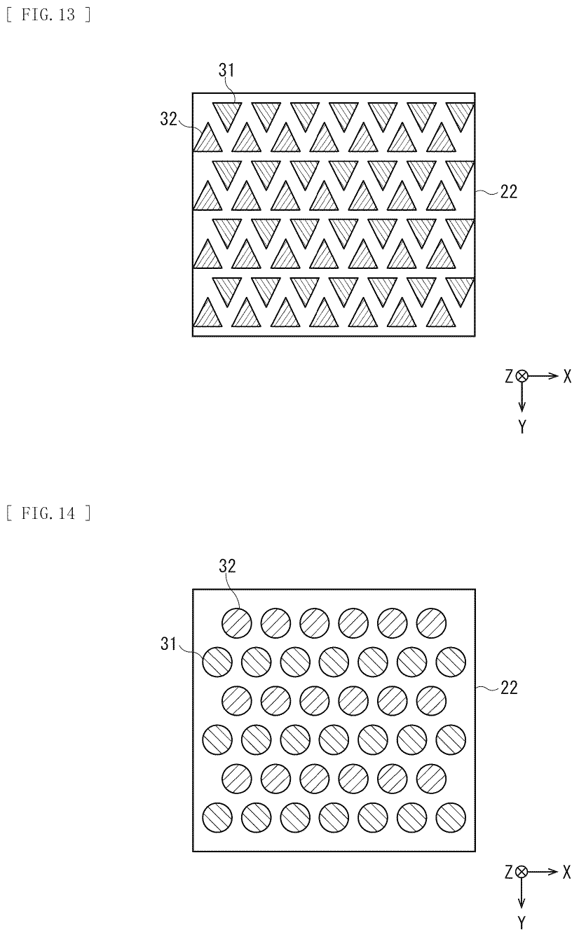

FIGS. 13 and 14 are diagrams illustrating an exemplary planar configuration of a photoelectric converter of the imaging device according to Modification Example 2. As in the example illustrated in FIG. 13, the structures 31 and the structures 32 may each have a triangular shape in plan view. Alternatively, the structures 31 and 32 may each have a circular shape in plan view as in the example illustrated in FIG. 14, or may each have an oval shape in plan view.

As illustrated in FIG. 13 or 14, the structures 31 and 32 may be included in the imaging device 1 at high density. This makes it possible to effectively apply an electric field to the photoelectric conversion film 22. It is to be noted that the structures 31 and 32 may each have a quadrangular shape in plan view. Alternatively, the structures 31 and 32 may each have a polygonal shape or another shape in plan view.

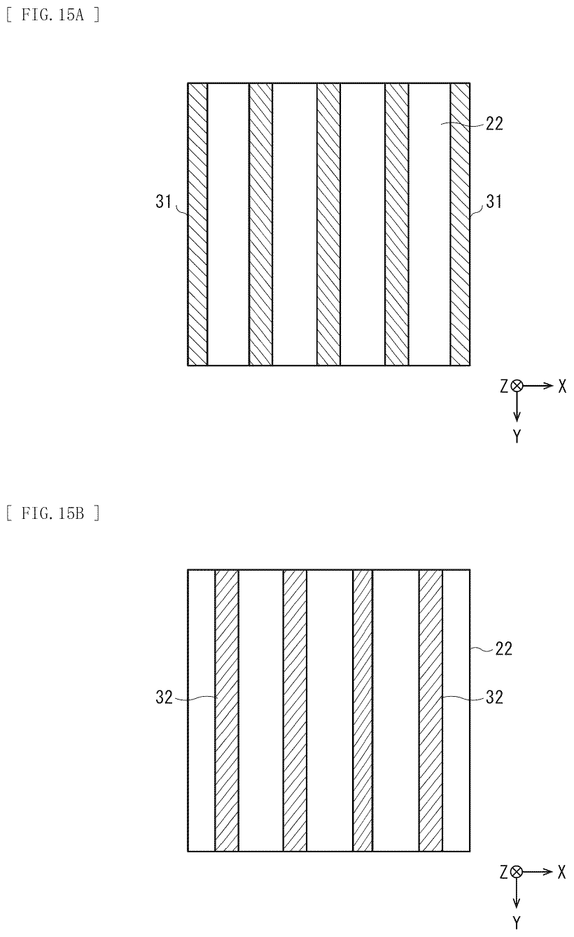

FIGS. 15A and 15B are diagrams illustrating another exemplary configuration of the photoelectric converter of the imaging device according to Modification Example 2. FIG. 15A illustrates an exemplary planar configuration of the multiple structures 31 of the photoelectric converter 11. FIG. 15B illustrates an exemplary planar configuration of the multiple structures 32 of the photoelectric converter 11. As in the examples illustrated in FIGS. 15A and 15B, the structures 31 and the structure 32 may each have a line (linear) shape. In other words, the structures 31 and the structures 32 may form a stripe pattern.

### 2-3. Modification Example 3

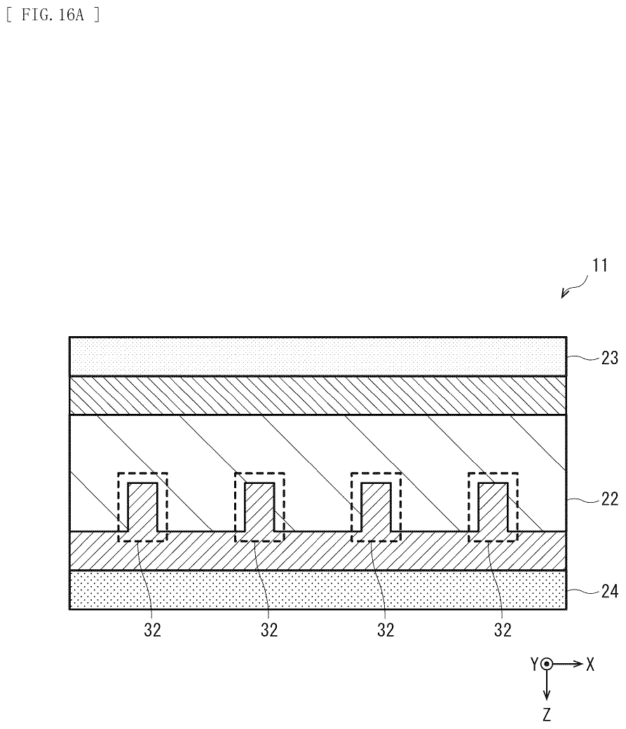

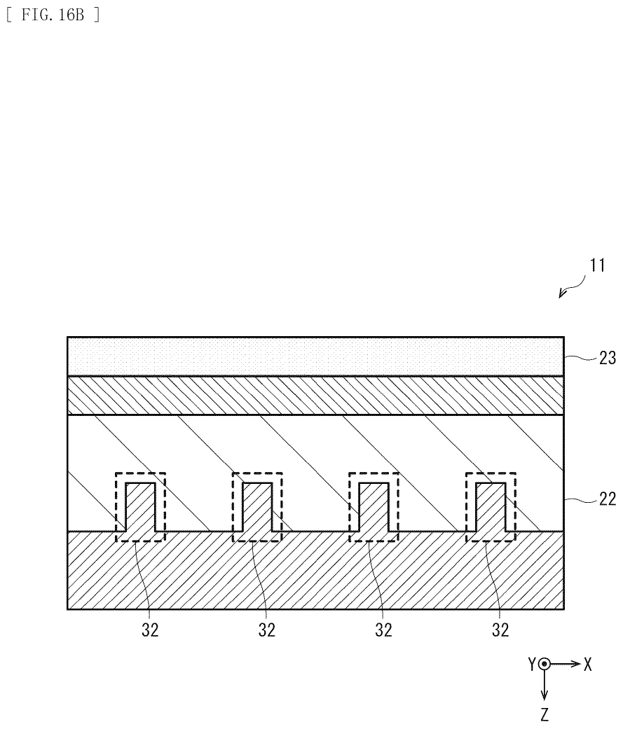

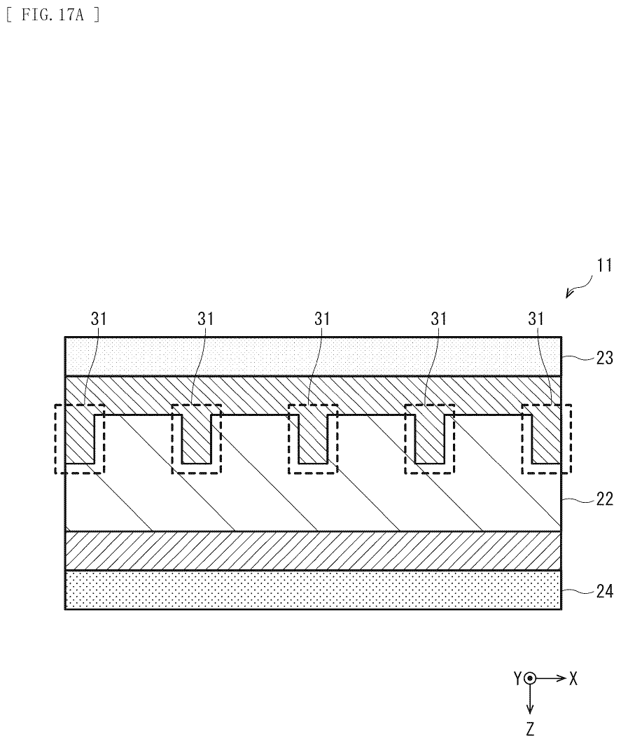

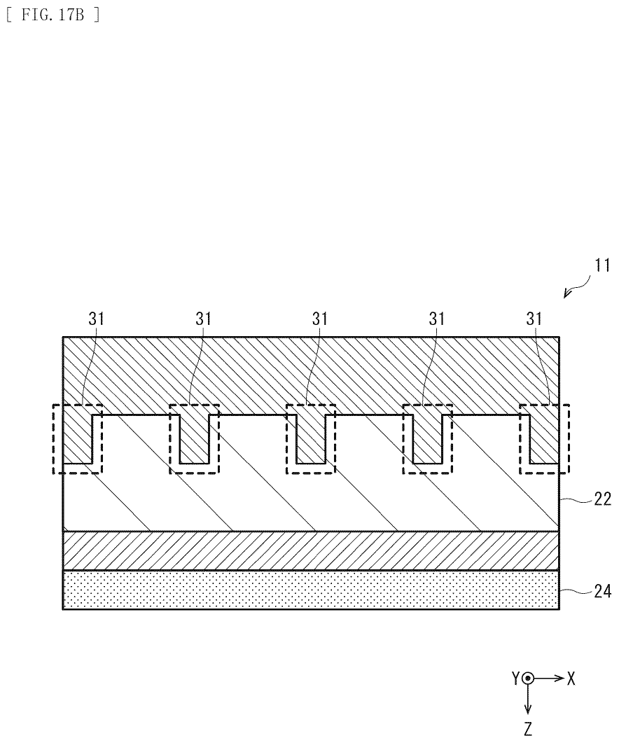

FIGS. 16A, 16B, 17A, and 17B are diagrams that illustrate an exemplary configuration of a photoelectric converter of an imaging device according to Modification Example 3. In the embodiment and the modification examples described above, the exemplary configuration of the photoelectric converter 11 including the structures 31 and the structures 32 is described. However, the photoelectric converter 11 may include only either the structures 31 or the structures 32.

As in the example illustrated in FIG. 16A, for example, only the structures 32 may be disposed without the structures 31 disposed. It is to be noted that the structures 32 may be integrated with the lower electrode 24. In the example illustrated in FIG. 16B, the structures 32 also serve as a lower electrode (read-out electrode). In other words, the multiple structures 32 may be a part of the lower electrode.

As in the example illustrated in FIG. 17A, only the structures 31 are provided without the structures 32 disposed. Further, the structures 31 may be integrated with the upper electrode 23. In the example illustrated in FIG. 17B, the structures 31 also serve as an upper electrode (common electrode). In other words, the multiple structures 31 may be a part of the upper electrode. It is to be noted that, also in the following modification examples, the photoelectric converter 11 may include only either the structures 31 or the structures 32. Further, also in the following modification examples, the structures 31 may be integrated with the upper electrode 23, and the structures 32 may be integrated with the lower electrode 24.

### 2-4. Modification Example 4

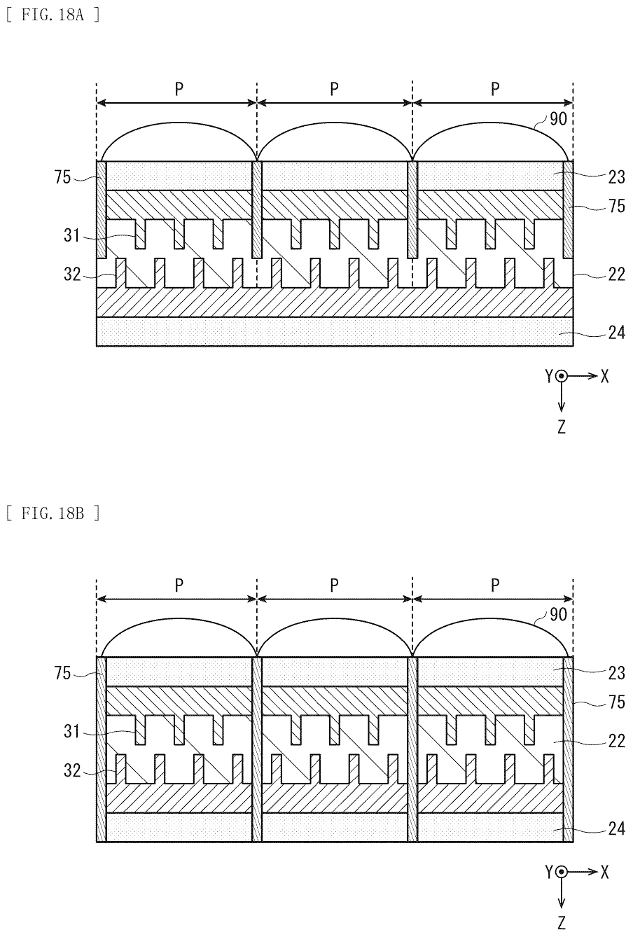

FIGS. 18A and 18B are diagrams illustrating an exemplary cross-sectional configuration of an imaging device according to Modification Example 4. As illustrated in FIGS. 18A and 18B, the imaging device 1 may include a separator 75. The separator 75 is formed in a trench (groove) provided at a boundary between each adjacent ones of the pixels P (or photoelectric converters 11). The separator has a deep trench isolation (DTI) structure, for example.

As in the example illustrated in FIG. 18A, for example, the separator 75 is provided to penetrate the upper electrode 23. The separator 75 is formed to extend in the Z-axis direction and reach to the inside of the photoelectric conversion film 22. The separator 75 is provided between the multiple structures 31. Providing the separator 75 makes it possible to suppress leakage of the electric charges generated through the photoelectric conversion at the photoelectric converter 11 of the pixel P into surrounding pixels P. Further, it is possible to suppress light leakage into the surrounding pixels P. It is therefore possible to suppress an occurrence of a crosstalk between the pixels.

In one example, an insulating film, which may be, for example, a silicon oxide film, is provided inside the trench of the separator 75. The trench of the separator 75 may be filled with polysilicon or a metal material, for example. Alternatively, the separator 75 may be formed using another dielectric material having low reflectance. For example, a void (cavity) may be provided inside the trench of the separator 75.

Providing a metal material or the like inside the trench of the separator 75 makes it possible to effectively suppress the light leakage into the surrounding pixels P. A predetermined potential (voltage) may be applied to the separator 75. The separator 75 may constitute a shield electrode by being applied with a vias voltage via a wiring line such as a wiring layer, for example.

As illustrated in FIG. 18B, the separator 75 may be provided to penetrate the upper electrode 23 and the lower electrode 24. The separator 75 includes a fill trench isolation (FTI) structure, for example. The separator 75 is provided between the multiple structures 31 and the multiple structures 32. In this Modification Example, providing the separator 75 makes it possible to suppress mixture of the pixel signals with noises.

### 2-5. Modification Example 5

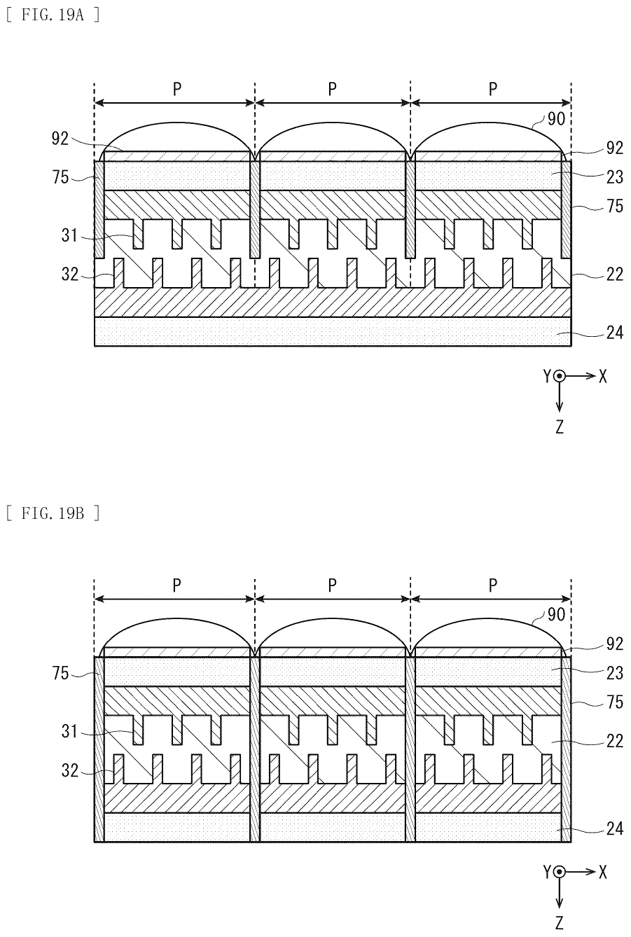

FIGS. 19A and 19B are diagrams illustrating an exemplary cross-sectional configuration of an imaging device according to Modification Example 5. As illustrated in FIGS. 19A and 19B, the imaging device 1 may include a filter 92. The lens 90 and the filter 92 are provided on a side on which light from the optical system is incident. The photoelectric converter 11 photoelectrically converts light entering via the lens 90 and the filter 92.

The filter 92 is configured to selectively transmit light in a specific wavelength range out of incident light. The filter 92 is a filter that cuts visible light and near-infrared light (NIR-cut filter), for example. Further, the filter 92 is a filter that transmits infrared light (near-infrared light (NIR light) and short-wave infrared light (SWIR light). The filter 92 is provided above the photoelectric converter 11 for each pixel P or for a plurality of pixels P, for example. It is to be noted that the filter 92 may be a RGN color filter provided for each pixel P of the pixel unit 100. The filter 92 may be a color filter for a complementary color such as cyan (Cy), magenta (Mg), or yellow (Ye).

### 2-6. Modification Example 6

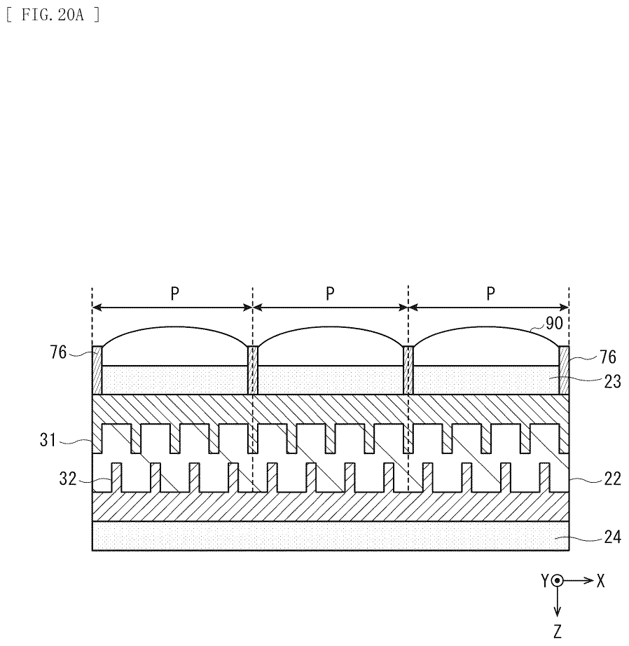

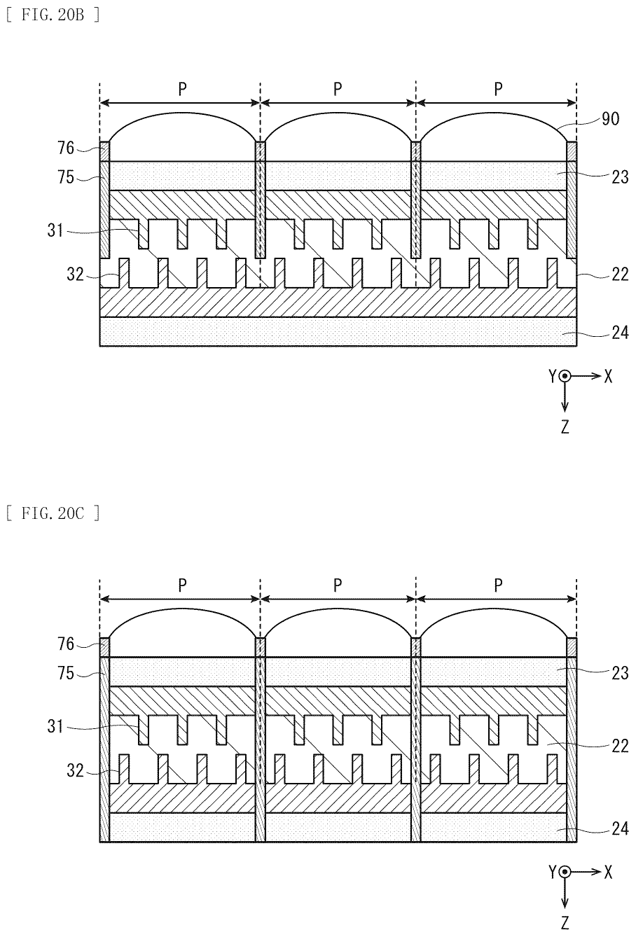

FIGS. 20A to 20C are diagrams illustrating an exemplary cross-sectional configuration of an imaging device according to Modification Example 6. As illustrated in FIG. 20A, the imaging device 1 may include a separation wall 76. The separation wall 76 includes, for example, a metal material, and is provided between each adjacent ones of the plurality of lenses 90. It is to be noted that the separation wall 76 may include a low-reflectance material. It is to be noted that the separation wall 76 may be formed between the filters 92 described above.

In this Modification Example, providing the separation wall 76 makes it possible to suppress a crosstalk. It is to be noted that, as illustrated in FIG. 20B or 20C, the separation wall 76 and the separator 75 may be provided in each pixel P of the imaging device 1. It is to be noted that, as in the example illustrated in FIG. 20C, the separator 75 may be provided to penetrate the upper electrode 23 and the lower electrode 24.

### 2-7. Modification Example 7

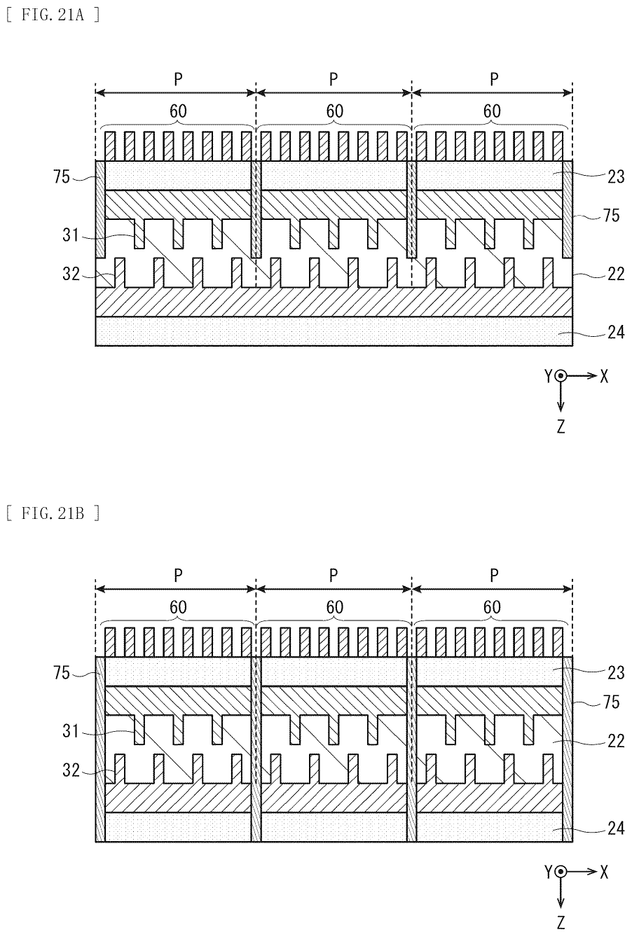

FIGS. 21A and 21B are diagrams illustrating an exemplary cross-sectional configuration of an imaging device according to Modification Example 7. The imaging device 1 may include a light-guiding member 60. The light-guiding member 60 (light guide) is configured to change an advancing direction of the incident light based on a difference in reflectance between multiple nano-structures (also referred to as microscopic structures, nanoposts, or the like) and a surrounding medium, and collect the light. In other words, the light-guiding member 60 is an optical element (meta-lens) that collects light by meta-surface technology. It is to be noted that, as illustrated in FIG. 21A or 21B, the imaging device 1 may include the separator 75. As in the example illustrated in FIG. 21B, the separator 75 may be provided to penetrate the upper electrode 23 and the lower electrode 24.

### 3. Application Examples

### Application Example 1

The light detecting device (imaging device 1) described above is applicable to various electronic apparatuses including an imaging system such as a digital still camera or a digital video camera, a mobile phone with an imaging function, or another device with an imaging function.

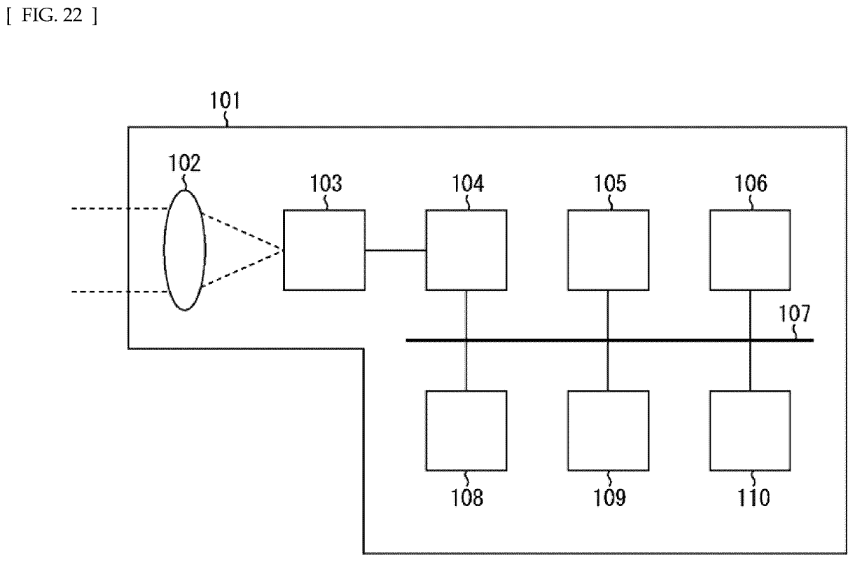

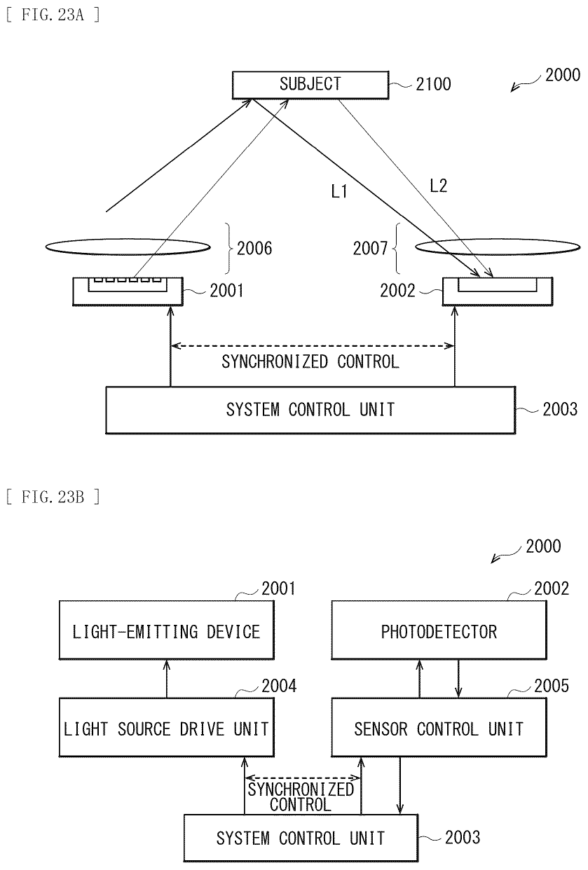

FIG. 22 is a block diagram illustrating an exemplary configuration of an electronic apparatus.

As illustrated in FIG. 22, the electronic apparatus 101 is provided with an optical system 102, a light detecting device 103, and a digital signal processor (DSP) 104. The electronic apparatus 101 is coupled to the DSP 104, a display device 105, an operation system 106, a memory 108, a recording device 109, and a power system 110 via a bus 107. The electronic apparatus 101 is configured to capture a still image and a moving image.

The optical system 102 includes one or more lens to guide image light (incident light) from the subject to the light detecting device 103 and to focus the image light on a light receiving surface (sensor unit) of the light detecting device 103.

The light detecting device (imaging device 1) described above may be employed as the light detecting device 103. In the light detecting device 103, electrons are accumulated for a predetermined period, in accordance with the image focused on the light reception surface via the optical system 102. Thereafter, signals corresponding to the electrons accumulated in the light detecting device 103 are supplied to the DSP 104.

The DSP 104 performs various kinds of signal processing on the signals from the light detecting device 103 to thereby acquire an image, and temporarily stores data on the image in the memory 108. The data on the image stored in the memory 108 is recorded in the recording device 109 or supplied to the display device 105 to thereby display the image. Further, the operation system 106 supplies an operation signal to each block of the electronic apparatus 101 in response to various user operations. The power system 110 supplies electric power necessary to drive each block of the electronic apparatus 101.

### Application Example 2

FIG. 23A schematically illustrates an exemplary overall configuration of a light detecting system 2000 including the light detecting device (imaging device 1). FIG. 23B schematically illustrates an exemplary circuit configuration of the light detecting system 2000. The light detecting system 2000 includes a light-emitting device 2001 as a light source unit that emits light L2, and a light detecting device 2002 as a light receiving unit that includes photoelectric conversion elements.

The light detecting device (imaging device 1) described above may be used as the light detecting device 2002. The light detecting system 2000 may further include a system control unit 2003, a light source drive unit 2004, a sensor control unit 2005, a light-source-side optical system 2006, and a camera-side optical system 2007.

The light detecting device 2002 is configured to detect light L1 and light L2. The light L1 is outside environment light reflected by a subject 2100 (measurement target) (refer to FIG. 23A). The light L2 is light reflected by the subject 2100 out of the light emitted from the light-emitting device 2001. The light L1 is, for example, visible light, and the light L2 is, for example, infrared light.

The light L1 may be detected by a photoelectric converter in the light detecting device 2002, and the light L2 may be detected by a photoelectric converter in the light detecting device 2002. Image information on the subject 2100 may be acquired from the light L1, and distance information between the subject 2100 and the light detecting system 2000 may be acquired from the light L2.

The light detecting system 2000 may be mounted on an electronic apparatus such as a smartphone or a mobile body such as a vehicle, for example. The light-emitting device 2001 may be configured by a semiconductor laser, a surface-emitting semiconductor laser, and a vertical cavity surface emitting laser (VCSEL), for example.

Employed as a method of detecting the light L2 emitted from the light-emitting device 2001 with the light detecting device 2002 may be, for example, an iTOF method; however, this is non-limiting. In the iTOF method, the photoelectric converter may be configured to measure a distance to the subject 2100 based on a time-of-flight (TOF), for example.

Employed as a method of detecting the light L2 emitted from the light-emitting device 2001 with the light detecting device 2002 may be, for example, a structured light method and a stereovision method. For example, in the structured light method, the distance between the light detecting system 2000 and the subject 2100 may be measured by projecting light having a predetermined pattern on the subject 2100 and analyzing the degree of distortion of the pattern.

In the stereovision method, the distance between the light detecting system 2000 and the subject may be measured by acquiring two or more images of the subject 2100 viewed from two or more different points of view using two or more cameras, for example. It is to be noted that the light-emitting device 2001 and the light detecting device 2002 may be controlled in synchronization with each other by the system control unit 2003.

### 4. Practical Examples

### Practical Examples to Mobile Bodies

The technology (the present technology) according to the present disclosure is applicable to a variety of products. For example, the technology according to the present disclosure may be achieved as a device mounted on any type of mobile body such as an automobile, an electric vehicle, a hybrid electric vehicle, a motorcycle, a bicycle, a personal mobility, an aircraft, a drone, a vessel, or a robot.

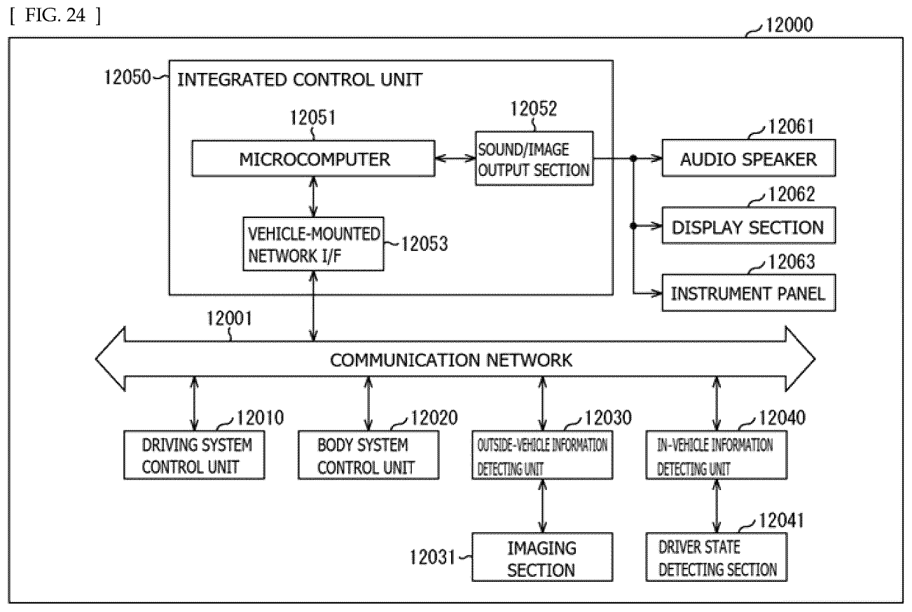

FIG. 24 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 24, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 24, an audio speaker 12061, a display section 12062, and an instrument panel 12063 are illustrated as the output device. The display section 12062 may, for example, include at least one of an on-board display and a head-up display.

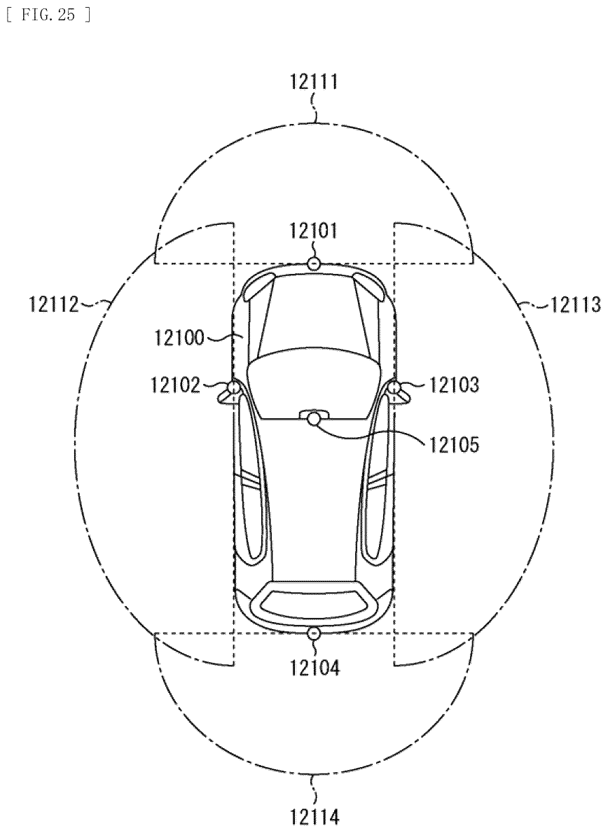

FIG. 25 is a diagram depicting an example of the installation position of the imaging section 12031.

In FIG. 25, a vehicle 12100 includes imaging sections 12101, 12102, 12103, 12104, and 12105 as the imaging section 12031.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The image of the front obtained by the imaging section 12101 and 12105 are used mainly to detect a preceding vehicle, a pedestrian, an obstacle, a signal, a traffic sign, a lane, or the like.

Incidentally, FIG. 25 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The example of the mobile body control system to which the technology according to the present disclosure is applicable has been described above. The technology according to the present disclosure is applicable to the imaging section 12031 out of the configurations described above, for example. Specifically, the imaging device 1 or the like is applicable to the imaging section 12031, for example. Applying the technology according to the present disclosure to the imaging section 12031 makes it possible to obtain a high-resolution captured image. It is therefore possible for the mobile body control system to perform high-resolution control based on the captured image.

### Practical Examples to Endoscopic Surgery System

The technology according to the present disclosure (present technology) is applicable to a variety of products. For example, the technology according to the present disclosure may be applied to an endoscopic surgery system.

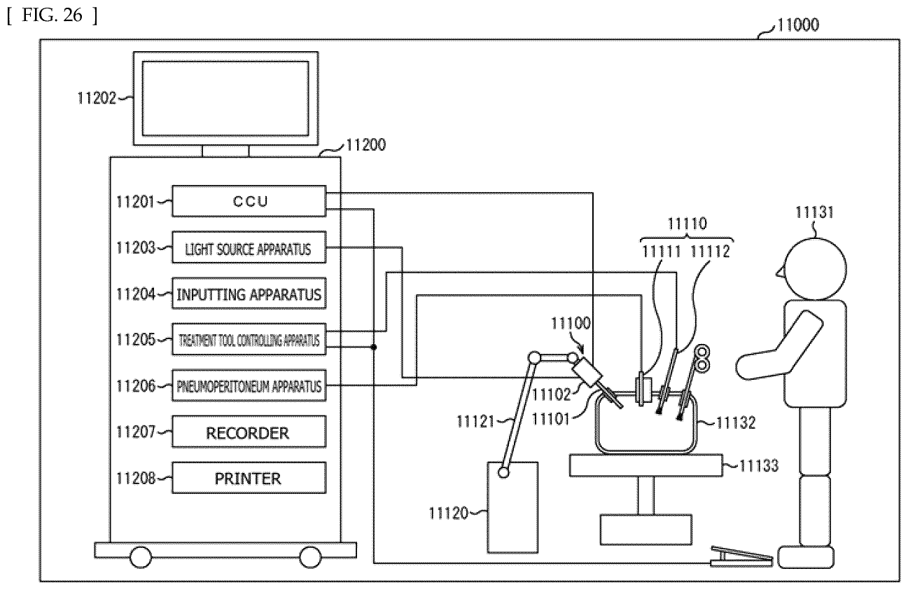

FIG. 26 is a view depicting an example of a schematic configuration of an endoscopic surgery system to which the technology according to an embodiment of the present disclosure (present technology) can be applied.

In FIG. 26, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy treatment tool 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body lumen of the patient 11132, and a camera head 11102 connected to a proximal end of the lens barrel 11101. In the example depicted, the endoscope 11100 is depicted which includes as a hard mirror having the lens barrel 11101 of the hard type. However, the endoscope 11100 may otherwise be included as a soft mirror having the lens barrel 11101 of the soft type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body lumen of the patient 11132 through the objective lens. It is to be noted that the endoscope 11100 may be a direct view mirror or may be a perspective view mirror or a side view mirror.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy treatment tool 11112 for cautery or incision of a tissue, sealing of a blood vessel or the like. A pneumoperitoneum apparatus 11206 feeds gas into a body lumen of the patient 11132 through the pneumoperitoneum tube 11111 to inflate the body lumen in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

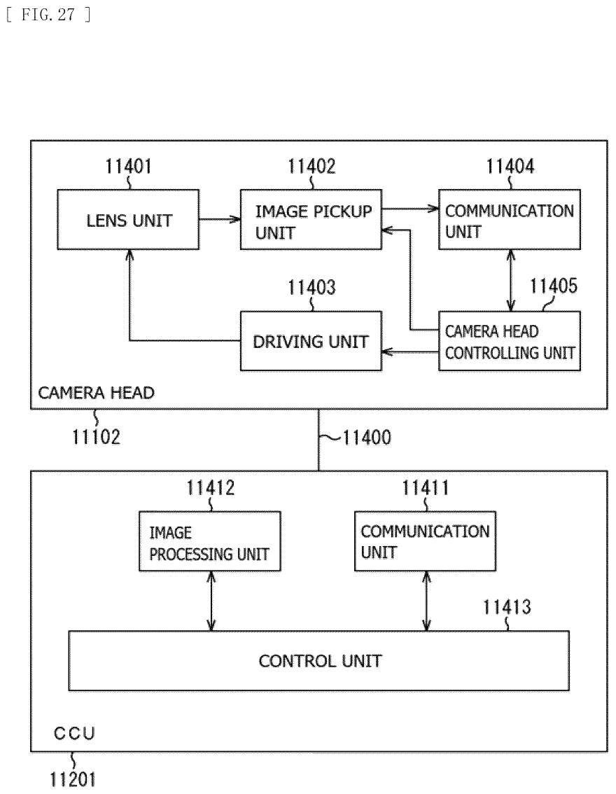

FIG. 27 is a block diagram depicting an example of a functional configuration of the camera head 11102 and the CCU 11201 depicted in FIG. 26.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy treatment tool 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

ere, while, in the example depicted, communication is performed by wired communication using the transmission cable 11400, the communication between the camera head 11102 and the CCU 11201 may be performed by wireless communication.

The example of the endoscopic surgery system to which the technology according to the present disclosure is applicable has been described above. The technology according to the present disclosure is preferably applied to the image pickup unit 11402 provided in the camera head 11102 of the endoscope 11100 out of the configurations described above. Applying the technology according to the present disclosure to the image pickup unit 11402 makes it possible to provide a high-resolution endoscope 11100.

Although the present disclosure has been described with reference to the embodiments, modification examples, application examples, and practical examples described above, the present technology is not limited to the embodiments and the like, and various modifications may be made. For example, although the above-described modification examples have been described as the modification examples of the above-described embodiments, the configurations of the modification examples may be combined as appropriate.

Although the description has been made by way of the imaging device in the embodiments or the like described above, the light detecting device of the present disclosure may be any device that receives incident light and converts the light into electric charges, for example. The signal to be outputted may be a signal of image information or a signal of a ranging information. The light detecting device (imaging device) may be applied to an image sensor or a ranging sensor, for example.

The light detecting device according to the present disclosure may be applied to a ranging sensor configured to measure a distance by a time of flight (TOF) method. The light detecting device (imaging device) may be applicable to a sensor configured to be driven by an event, such as an event vision sensor (EVS), an event driven sensor (EDS), or a dynamic vision sensor (DVS).

The light detecting device according to an embodiment of the present disclosure includes the first electrode, the second electrode, the multiple first structures provided close to the first electrode between the first electrode and the second electrode, and the photoelectric conversion film provided between the multiple first structures and the second electrode. It is therefore possible to achieve a light detecting device having excellent detection performance.

The light detecting device according to an embodiment of the present disclosure includes the photoelectric conversion film and the multiple first structures joined to each other with band bending. It is therefore possible to achieve a light detecting device having excellent detection performance.

It is to be noted that the effects described herein are mere examples and are not limited to those described, and other effects may also be made. Further, the present disclosure may be configured as follows.
(1) A light detection device including:
   a first electrode;
   a second electrode provided opposed to the first electrode;
   multiple first structures each provided close to the first electrode between the first electrode and the second electrode; and
   a photoelectric conversion film provided between the multiple first structures and the second electrode.
(2) The light detecting device according to (1), in which
   the multiple first structures provided close to the first electrode are arranged in a first direction, and
   a part of the photoelectric conversion film is provided between the multiple first structures.
(3) The light detecting device according to (1) or (2), in which the multiple first structures are integrated with each other.
(4) The light detecting device according to any one of (1) to (3), in which the first structure is an electrode joined to the photoelectric conversion film with band bending.
(5) The light detecting device according to any one of (1) to (4), in which the first structure includes a metal material or a semiconductor material.
(6) The light detecting device according to any one of (1) to (5), including multiple pixels each including a first photoelectric conversion element that includes the first electrode, the second electrode, the first structure, and the photoelectric conversion film.
(7) The light detecting device according to (6), further including a separator provided at a boundary between each adjacent ones of the multiple pixels.
(8) The light detecting device according to any one of (1) to (7), further including multiple second structures each provided close to the second electrode between the first electrode and the second electrode.
(9) The light detecting device according to (8), in which the photoelectric conversion film is provided between the multiple first structures and the multiple second structures.
(10) The light detecting device according to (8) or (9), in which
   the multiple second structures provided close to the second electrode are arranged in a first direction, and
   a part of the photoelectric conversion film is provided between the multiple second structures.
(11) The light detecting device according to any one of (8) to (10), in which
   the multiple first structures and the multiple second structures are arranged in the first direction and a second direction crossing the first direction, and
   the first structure and the second structure are provided with a part of the photoelectric conversion film interposed therebetween.
(12) The light detecting device according to any one of (8) to (11), in which the multiple second structures are integrated with each other.
(13) The light detecting device according to any one of (8) to (12), in which one or both of an interval between a lower end of the first structure and an upper end of the second structure and an interval between an upper end of the first structure and a lower end of the second structure are less than or equal to 1 micrometers.
(14) The light detecting device according to any one of (8) to (13), in which the second structure is an electrode joined to the photoelectric conversion film with band bending.
(15) The light detecting device according to any one of (8) to (14), in which the second structure includes a metal material or a semiconductor material.
(16) The light detecting device according to any one of (8) to (15), further including
   multiple pixels each including a first photoelectric conversion element that includes the first electrode, the second electrode, the first structure, and the photoelectric conversion film; and
   a separator provided at a boundary between each adjacent ones of the multiple pixels, in which
   at least a part of the separator is provided between the multiple first structures.
(17) The light detecting device according to (16), in which the separator is provided between the multiple first structures and between the multiple second structures.
(18) The light detecting device according to any one of (1) to (17), in which the first structure and the first electrode are integrated with each other.
(19) The light detecting device according to any one of (8) to (18), in which the second structure and the second electrode are integrated with each other.
(20) The light detecting device according to any one of (1) to (19), in which the photoelectric conversion film includes a quantum dot, an organic compound semiconductor, an inorganic compound semiconductor, germanium, silicon, or organic-inorganic perovskite.
(21) The light detecting device according to any one of (1) to (20), further including a read-out circuit configured to output a signal based on an electric charge obtained as a result of conversion at the photoelectric conversion film.
(22) A light detecting device including:
   a photoelectric conversion film; and
   multiple first structures each joined to the photoelectric conversion film with band bending.
(23) The light detecting device according to (22), including multiple pixels each including a first photoelectric conversion element that includes the photoelectric conversion film and the first structure.
(24) The light detecting device according to (23), further including a separator provided at a boundary between each adjacent ones of the multiple pixels.
(25) The light detecting device according to any one of (22) to (24), in which the multiple first structures are integrated with each other.
(26) The light detecting device according to any one of (22) to (25), further including
   multiple second structures each joined to the photoelectric conversion film with band bending, in which
   the photoelectric conversion film is provided between the multiple first structures and the multiple second structures.
(27) The light detecting device according to (26), further including:
   multiple pixels each including a first photoelectric conversion element that includes the photoelectric conversion film, the first structure, and the second structure; and
   a separator provided at a boundary between each adjacent ones of the multiple pixels, in which
   at least a part of the separator is provided between the multiple first structures.
(28) The light detecting device according to (26) or (27), in which the multiple second structures are integrated with each other.
(29) An electronic apparatus including:
   an optical system; and
   a light detecting device that receives light having passed through the optical system, in which
   the light detecting device includes
      a first electrode,
      a second electrode provided opposed to the first electrode,
      multiple first structures each provided close to the first electrode between the first electrode and the second electrode, and
      a photoelectric conversion film provided between the multiple first structures and the second electrode.
(30) The electronic apparatus according to (29), in which the light detecting device further includes multiple second structures each provided close to the second electrode between the first electrode and the second electrode.
(31) An electronic apparatus including:
   an optical system; and
   a light detecting device that receives light having passed through the optical system, in which
   the light detecting device includes
      a photoelectric conversion film, and
      multiple first structures each joined to the photoelectric conversion film with band bending.
(32) The electronic apparatus according to (31), in which
   the light detecting device further includes multiple second structures each joined to the photoelectric conversion film with band bending, and
   the photoelectric conversion film is provided between the multiple first structures and the multiple second structures.

The present application claims the benefit of Japanese Priority Patent Application JP2023-079921 filed with the Japan Patent Office on May 15, 2023, the entire contents of which are incorporated herein by reference.

It should be understood by those skilled in the art that various modifications, combinations, sub-combinations and alternations may occur depending on design requirements and other factors insofar as they are within the scope of the appended claims or the equivalents thereof.

What is claimed is:

1. A light detection device comprising:
a first electrode;
a second electrode provided opposed to the first electrode;
multiple first structures each provided close to the first electrode between the first electrode and the second electrode; and
a photoelectric conversion film provided between the multiple first structures and the second electrode.

2. The light detecting device according to claim 1, wherein
the multiple first structures provided close to the first electrode are arranged in a first direction, and
a part of the photoelectric conversion film is provided between the multiple first structures.

3. The light detecting device according to claim 1, wherein the multiple first structures are integrated with each other.

4. The light detecting device according to claim 1, wherein the first structure comprises an electrode joined to the photoelectric conversion film with band bending.

5. The light detecting device according to claim 1, wherein the first structure includes a metal material or a semiconductor material.

6. The light detecting device according to claim 1, comprising multiple pixels each including a first photoelectric conversion element that includes the first electrode, the second electrode, the first structure, and the photoelectric conversion film.

7. The light detecting device according to claim 6, further comprising a separator provided at a boundary between each adjacent ones of the multiple pixels.

8. The light detecting device according to claim 1, further comprising multiple second structures each provided close to the second electrode between the first electrode and the second electrode.

9. The light detecting device according to claim 8, wherein the photoelectric conversion film is provided between the multiple first structures and the multiple second structures.

10. The light detecting device according to claim 8, wherein
the multiple second structures provided close to the second electrode are arranged in a first direction, and
a part of the photoelectric conversion film is provided between the multiple second structures.

11. The light detecting device according to claim 10, wherein
the multiple first structures and the multiple second structures are arranged in the first direction and a second direction crossing the first direction, and
the first structure and the second structure are provided with a part of the photoelectric conversion film interposed therebetween.

12. The light detecting device according to claim 8, wherein the multiple second structures are integrated with each other.

13. The light detecting device according to claim 8, wherein one or both of an interval between a lower end of the first structure and an upper end of the second structure and an interval between an upper end of the first structure and a lower end of the second structure are less than or equal to 1 micrometers.

14. The light detecting device according to claim 8, wherein the second structure comprises an electrode joined to the photoelectric conversion film with band bending.

15. The light detecting device according to claim 8, wherein the second structure includes a metal material or a semiconductor material.

16. The light detecting device according to claim 8, further comprising
multiple pixels each including a first photoelectric conversion element that includes the first electrode, the second electrode, the first structure, and the photoelectric conversion film; and
a separator provided at a boundary between each adjacent ones of the multiple pixels, wherein
at least a part of the separator is provided between the multiple first structures.

17. The light detecting device according to claim 16, wherein the separator is provided between the multiple first structures and between the multiple second structures.

18. The light detecting device according to claim 1, wherein the first structure and the first electrode are integrated with each other.

19. The light detecting device according to claim 8, wherein the second structure and the second electrode are integrated with each other.

20. The light detecting device according to claim 1, wherein the photoelectric conversion film includes a quantum dot, an organic compound semiconductor, an inorganic compound semiconductor, germanium, silicon, or organic-inorganic perovskite.

21. The light detecting device according to claim 1, further comprising a read-out circuit configured to output a signal based on an electric charge obtained as a result of conversion at the photoelectric conversion film.

22. A light detecting device comprising:
a photoelectric conversion film; and
multiple first structures each joined to the photoelectric conversion film with band bending.

23. The light detecting device according to claim 22, comprising multiple pixels each including a first photoelectric conversion element that includes the photoelectric conversion film and the first structure.

24. The light detecting device according to claim 23, further comprising a separator provided at a boundary between each adjacent ones of the multiple pixels.

25. The light detecting device according to claim 22, wherein the multiple first structures are integrated with each other.

26. The light detecting device according to claim 22, further comprising
multiple second structures each joined to the photoelectric conversion film with band bending, wherein
the photoelectric conversion film is provided between the multiple first structures and the multiple second structures.

27. The light detecting device according to claim 26, further comprising:
multiple pixels each including a first photoelectric conversion element that includes the photoelectric conversion film, the first structure, and the second structure; and
a separator provided at a boundary between each adjacent ones of the multiple pixels, wherein
at least a part of the separator is provided between the multiple first structures.

28. The light detecting device according to claim 26, wherein the multiple second structures are integrated with each other.

29. An electronic apparatus comprising:
an optical system; and
a light detecting device that receives light having passed through the optical system, wherein
the light detecting device includes
a first electrode,
a second electrode provided opposed to the first electrode,
multiple first structures each provided close to the first electrode between the first electrode and the second electrode, and
a photoelectric conversion film provided between the multiple first structures and the second electrode.

30. The electronic apparatus according to claim 29, wherein the light detecting device further includes multiple second structures each provided close to the second electrode between the first electrode and the second electrode.

31. An electronic apparatus comprising:
an optical system; and
a light detecting device that receives light having passed through the optical system, wherein
the light detecting device includes
a photoelectric conversion film, and
multiple first structures each joined to the photoelectric conversion film with band bending.

32. The electronic apparatus according to claim 31, wherein
the light detecting device further includes multiple second structures each joined to the photoelectric conversion film with band bending, and
the photoelectric conversion film is provided between the multiple first structures and the multiple second structures.
